(19) United States
(12) Patent Application Publication
(10) Pub. No.: US 2025/0228026 A1
(43) Pub. Date: Jul. 10, 2025

(54) IMAGE SENSOR HAVING NANO-PHOTONIC LENS ARRAY AND ELECTRONIC APPARATUS INCLUDING THE IMAGE SENSOR

(71) Applicant: SAMSUNG ELECTRONICS CO., LTD., Suwon-si (KR)

(72) Inventors: Sookyoung ROH, Suwon-si (KR); Seokho YUN, Suwon-si (KR)

(73) Assignee: SAMSUNG ELECTRONICS CO., LTD., Suwon-si (KR)

(21) Appl. No.: 18/920,431

(22) Filed: Oct. 18, 2024

(30) Foreign Application Priority Data
Jan. 9, 2024 (KR) 10-2024-0003633

(51) Int. Cl. H01L 27/146

(52) U.S. Cl. CPC H10F 39/8063; H10F 39/8023; H10F 39/803

(57) ABSTRACT

Provided is an image sensor including: a sensor substrate including a plurality of light sensing devices; and a nano-photonic lens array including a plurality of nanostructures arranged to separate, from incident light, light in a first wavelength band, light in a second wavelength band different from the first wavelength band, and light in a third wavelength band different from the first wavelength band and the second wavelength band, and to focus the separated light onto each of the plurality of light sensing devices, wherein the plurality of nanostructures are configured to cause light of a same wavelength to be focused onto each of two light sensing devices adjacent in a diagonal direction among the plurality of light sensing devices, and wherein, for each of the two light sensing devices adjacent in the diagonal direction, the light of the same wavelength respectively focused thereon has a different intensity.

### CROSS-REFERENCE TO RELATED APPLICATION

This application is based on and claims priority to Korean Patent Application No. 10-2024-0003633, filed on Jan. 9, 2024, in the Korean Intellectual Property Office, the disclosure of which is incorporated by reference herein in its entirety.

### BACKGROUND

### 1. Field

The disclosure relates to an image sensor including a nano-photonic lens array and an electronic apparatus including the image sensor.

### 2. Description of the Related Art

Image sensors generally sense the color of incident light by using a color filter. However, a color filter may have low light utilization efficiency because the color filter absorbs light of colors other than the intended color of light. For example, in the case in which a red-green-blue (RGB) color filter is used, only ⅓ of the incident light is transmitted therethrough, and the other part of the incident light, that is, ⅔ of the incident light, is absorbed. Thus, the light utilization efficiency is only about 33%. Thus, in a color display apparatus or a color image sensor, most light loss occurs in the color filter.

### SUMMARY

Provided are an image sensor including a nano-photonic lens array and having an improved optical efficiency, and an electronic apparatus including the image sensor.

Additional aspects will be set forth in part in the description which follows and, in part, will be apparent from the description, or may be learned by practice of the presented embodiments of the disclosure.

According to an aspect of the disclosure, an image sensor includes: a sensor substrate including a plurality of light sensing devices; and a nano-photonic lens array including a plurality of nanostructures arranged to separate, from incident light, light in a first wavelength band, light in a second wavelength band different from the first wavelength band, and light in a third wavelength band different from the first wavelength band and the second wavelength band, and to focus the separated light onto each of the plurality of light sensing devices, wherein the plurality of nanostructures are configured to cause light of a same wavelength to be focused onto each of two light sensing devices adjacent in a diagonal direction among the plurality of light sensing devices, and wherein, for each of the two light sensing devices adjacent in the diagonal direction, the light of the same wavelength respectively focused thereon has a different intensity.

The plurality of light sensing devices may include a first main light sensing device, a second main light sensing device, a third main light sensing device, and a fourth main light sensing device which are arranged in a 2×2 array in a first direction and a second direction perpendicular to the first direction, and the plurality of light sensing devices may further include a first corner light sensing device in contact with the first main light sensing device in the diagonal direction, a second corner light sensing device in contact with the second main light sensing device in the diagonal direction, a third corner light sensing device in contact with the third main light sensing device in the diagonal direction, and a fourth corner light sensing device in contact with the fourth main light sensing device in the diagonal direction.

The first main light sensing device may be larger than the first corner light sensing device, the second main light sensing device may be larger than the second corner light sensing device, the third main light sensing device may be larger than the third corner light sensing device, and the fourth main light sensing device may be larger than the fourth corner light sensing device.

The nano-photonic lens array may include a first main meta region corresponding to the first main light sensing device, a first corner meta region corresponding to the first corner light sensing device, a second main meta region corresponding to the second main light sensing device, a second corner meta region corresponding to the second corner light sensing device, a third main meta region corresponding to the third main light sensing device, a third corner meta region corresponding to the third corner light sensing device, a fourth main meta region corresponding to the fourth main light sensing device, and a fourth corner meta region corresponding to the fourth corner light sensing device.

The first main meta region may be larger than the first corner meta region, the second main meta region may be larger than the second corner meta region, the third main meta region may be larger than the third corner meta region, and the fourth main meta region may be larger than the fourth corner meta region.

The plurality of nanostructures may include a first plurality of nanostructures, a second plurality of nanostructures, a third plurality of nanostructures, and a fourth plurality of nanostructures. The first main meta region, the second main meta region, the third main meta region, and the fourth main meta region may respectively include the first plurality of nanostructures, the second plurality of nanostructures, the third plurality of nanostructures, and the fourth plurality of nanostructures. Each nanostructure of each of the first, the second, the third, and the fourth plurality of nanostructures may include a cross-sectional area and may have a position. The cross-sectional areas of at least two nanostructures, within each of the first, the second, the third, and the fourth plurality of nanostructures, may be different. The first corner meta region, the second corner meta region, the third corner meta region, and the fourth corner meta region each may include at least one nanostructure.

The position and the cross-sectional area of each nanostructure of each of the first, the second, the third, and the fourth plurality of nanostructures may be configured to: cause the light in the first wavelength band to be focused onto each of the first main light sensing device, the first corner light sensing device, the fourth main light sensing device, and the fourth corner light sensing device; cause the light in the second wavelength band to be focused onto each of the second main light sensing device and the second corner light sensing device; and cause the light in the third wavelength band to be focused onto each of the third main light sensing device and the third corner light sensing device.

The position and the cross-sectional area of each nanostructure of each of the first, the second, the third, and the fourth plurality of nanostructures may be configured to: cause an intensity of the light in the first wavelength band focused onto the first main light sensing device to be greater than an intensity of the light in the first wavelength band focused onto the first corner light sensing device; cause an intensity of the light in the second wavelength band focused onto the second main light sensing device to be greater than an intensity of the light in the second wavelength band focused onto the second corner light sensing device; cause an intensity of the light in the third wavelength band focused onto the third main light sensing device to be greater than an intensity of the light in the third wavelength band focused onto the third corner light sensing device; and cause an intensity of the light in the first wavelength band focused onto the fourth main light sensing device to be greater than an intensity of the light in the first wavelength band focused onto the fourth corner light sensing device.

A distribution of the cross-sectional areas of the first plurality of nanostructures may be symmetrical with respect to a diagonal line passing through a center of the first main meta region in a first diagonal direction and a diagonal line passing through the center of the first main meta region in a second diagonal direction. A distribution of the cross-sectional areas of the fourth plurality of nanostructures may be symmetrical with respect to a diagonal line passing through a center of the fourth main meta region in the first diagonal direction and a diagonal line passing through the center of the fourth main meta region in the second diagonal direction. The first diagonal direction may intersect the second diagonal direction.

The distribution of the cross-sectional areas of the first plurality of nanostructures may be asymmetrical with respect to a line passing through the center of the first main meta region in the first direction and a line passing through the center of the first main meta region in the second direction, and the distribution of the cross-sectional areas of the fourth plurality of nanostructures in the fourth main meta region may be asymmetrical with respect to a line passing through the center of the fourth main meta region in the first direction and a line passing through the center of the fourth main meta region in the second direction.

The distribution of the cross-sectional areas of the first plurality of nanostructures and the distribution of the cross-sectional areas of the fourth plurality of nanostructures may be the same.

A distribution of the cross-sectional areas of the second plurality of nanostructures may be symmetrical with respect to a line passing through a center of the second main meta region in the first direction, a line passing through the center of the second main meta region in the second direction, a diagonal line passing through the center of the second main meta region in the first diagonal direction, and a diagonal line passing through the center of the center of the second main meta region in the second diagonal direction; and a distribution of the cross-sectional areas of the third plurality of nanostructures may be symmetrical with respect to a line passing through a center of the third main meta region in the first direction, a line passing through the center of the third main meta region in the second direction, a diagonal line passing through the center of the third main meta region in the first diagonal direction, and a diagonal line passing through the center of the center of the third main meta region in the second diagonal direction.

The distribution of the cross-sectional areas of the second plurality of nanostructures may be different from the distribution of the cross-sectional areas of the third plurality of nanostructures.

The distribution of the cross-sectional areas of the second plurality of nanostructures and the distribution of the cross-sectional areas of the third plurality of nanostructures may be the same.

The distribution of the cross-sectional areas of the second plurality of nanostructures may be symmetrical with respect to a diagonal line passing through the center of the second main meta region and a diagonal line passing through the center of the second main meta region, and may be asymmetrical with respect to a line passing through the center of the second main meta region in the first direction and a line passing through the center of the second main meta region in the second direction; and the distribution of the cross-sectional areas of the third plurality of nanostructures may be symmetrical with respect to a diagonal line passing through the center of the third main meta region in the first diagonal direction and a diagonal line passing through the center of the third main meta region in the second diagonal direction, and may be asymmetrical with respect to a line passing through the center of the third main meta region in the first direction and a line passing through the center of the third main meta region in the second direction.

The plurality of light sensing devices may include a plurality of first light sensing devices, a plurality of second light sensing devices, a plurality of third light sensing devices, a plurality of fourth light sensing devices, a plurality of fifth light sensing devices, and a plurality of sixth light sensing devices which all have a same size and are two-dimensionally arranged in a first diagonal direction and a second diagonal direction. The plurality of first light sensing devices and the plurality of second light sensing devices may be alternately arranged in the second diagonal direction. The plurality of third light sensing devices, the plurality of fourth light sensing devices, the plurality of fifth light sensing devices, and the plurality of sixth light sensing devices may be repeatedly arranged in the forgoing sequence in the second diagonal direction.

The nano-photonic lens array may include a plurality of first meta regions corresponding to the plurality of first light sensing devices, a plurality of second meta regions corresponding to the plurality of second light sensing devices, a plurality of third meta regions corresponding to the plurality of third light sensing devices, a plurality of fourth meta regions corresponding to the plurality of fourth light sensing devices, a plurality of fifth meta regions corresponding to the plurality of fifth light sensing devices, and a plurality of sixth meta regions corresponding to the plurality of sixth light sensing devices, and each of the plurality of first meta regions, the plurality of second meta regions, the plurality of third meta regions, the plurality of fourth meta regions, the plurality of fifth meta regions, and the plurality of sixth meta regions may include a plurality of nanostructures.

A number of the plurality of nanostructures in the plurality of first meta regions may be greater than a number of the plurality of nanostructures in the plurality of second meta regions, a number of the plurality of nanostructures in the plurality of third meta regions may be greater than a number of the plurality of nanostructures in the plurality of fourth meta regions, and a number of the plurality of nanostructures in the plurality of fifth meta regions may be greater than a number of the plurality of nanostructures in the plurality of sixth meta regions.

Distributions of the cross-sectional areas of the plurality of nanostructures in each of the plurality of first meta regions may be symmetrical with respect to respective diagonal lines passing through centers of the plurality of first meta regions in the first diagonal direction and respective diagonal lines passing through the centers of the plurality of first meta regions in the second diagonal direction, and may be asymmetrical with respect to respective lines passing through the centers of the plurality of first meta regions in the first direction and respective lines passing through the centers of the plurality of first meta regions in the second direction. Distributions of the cross-sectional areas of the plurality of nanostructures in the plurality of second meta regions may be symmetrical with respect to respective diagonal lines passing through centers of the plurality of second meta regions in the first diagonal direction and respective diagonal line passing through the centers of the plurality of second meta regions in the second diagonal direction, and may be asymmetrical with respect to respective lines passing through the centers of the plurality of second meta regions in the first direction and respective lines passing through the centers of the plurality of second meta regions in the second direction. Distributions of the cross-sectional areas of the plurality of nanostructures in the plurality of third meta regions may be symmetrical with respect to respective diagonal lines passing through centers of the plurality of third meta regions in the first diagonal direction and respective diagonal lines passing through the centers of the plurality of third meta regions in the second diagonal direction, and may be asymmetrical with respect to respective lines passing through the centers of the plurality of third meta regions in the first direction and respective lines passing through the centers of the plurality of third meta regions in the second direction. Distributions of the cross-sectional areas of the plurality of nanostructures in the plurality of fourth meta regions may be symmetrical with respect to respective diagonal lines passing through centers of the plurality of fourth meta regions in the first diagonal direction and respective diagonal lines passing through the centers of the plurality of fourth meta regions in the second diagonal direction, and may be asymmetrical with respect to respective lines passing through the centers of the plurality of fourth meta regions in the first direction and respective lines passing through the centers of the plurality of fourth meta regions in the second direction. Distributions of the cross-sectional areas of the plurality of nanostructures in the plurality of fifth meta regions may be symmetrical with respect to respective diagonal lines passing through centers of the plurality of fifth meta regions in the first diagonal direction and respective diagonal lines passing through the centers of the plurality of fifth meta regions in the second diagonal direction, and may be asymmetrical with respect to respective lines passing through the centers of the plurality of fourth meta regions in the first direction and respective lines passing through the centers of the plurality of fourth meta regions in the second direction. Distributions of the cross-sectional areas of the plurality of nanostructures in the plurality of sixth meta regions may be symmetrical with respect to respective diagonal lines passing through centers of the plurality of sixth meta regions in the first diagonal direction and respective diagonal lines passing through centers of the plurality of sixth meta regions in the second diagonal direction, and may be asymmetrical with respect to respective lines passing through the centers of the plurality of sixth meta regions in the first direction and respective lines passing through the centers of the plurality of sixth meta regions in the second direction.

According to an aspect of the disclosure, an electronic apparatus includes: a lens assembly configured to form an optical image of a subject; an image sensor configured to convert the optical image formed by the lens assembly into an electrical signal; at least one memory storing one or more instructions; and at least one processor configured to execute the one or more instructions, wherein the one or more instructions, when executed by the at least one processor, cause the electronic apparatus to process a signal generated by the image sensor, wherein the image sensor includes: a sensor substrate including a plurality of light sensing devices; and a nano-photonic lens array including a plurality of nanostructures arranged to separate, from incident light, light in a first wavelength band, light in a second wavelength band different from the first wavelength band, and light in a third wavelength band different from the first wavelength band and the second wavelength band, and to focus the separated light onto each of the plurality of light sensing devices, wherein the plurality of nanostructures are configured to cause light of a same wavelength to be focused onto each of two light sensing devices adjacent in a diagonal direction among the plurality of light sensing devices, and wherein, for each of the two light sensing devices adjacent in the diagonal direction, the light of the same wavelength respectively focused thereon has a different intensity.

According to an aspect of the disclosure, an image sensor includes: a sensor substrate including a main light sensing device and a corner light sensing device in contact with the main light sensing device; and a nano-photonic lens array including a main meta region and a corner meta region, wherein the main meta region includes a plurality of nanostructures, and the corner meta region includes at least one nanostructure, wherein the plurality of nanostructures is arranged to separate light of a wavelength band from incident light, wherein the plurality of nanostructures is configured to cause the light of the wavelength band to be focused onto the main light sensing device and the corner light sensing device, and wherein the light of the wavelength band focused on the main light sensing device has a different intensity than the light of the wavelength band focused on the corner light sensing device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an image sensor according to an embodiment;

FIG. 2 is a diagram showing an example of a pixel arrangement in a pixel array of an image sensor, according to an embodiment;

FIGS. 3A, 3B, 3C and 3D are cross-sectional views schematically showing a structure of a pixel array in an image sensor, according to an embodiment;

FIG. 4 is a plan view showing an example of an arrangement of a plurality of nanostructures in a nano-photonic lens array of FIGS. 3A to 3D;

FIGS. 5A, 5B, and 5C are diagrams showing examples of a phase profile of green light passing through the nano-photonic lens array of FIG. 4;

FIG. 6A is a diagram showing an example of an array of green light focusing regions formed by a nano-photonic lens array;

FIG. 6B is a diagram showing an example of an array of red light focusing regions formed by the nano-photonic lens array;

FIG. 6C is a diagram showing an example of an array of blue light focusing regions formed by the nano-photonic lens array;

FIG. 7 is a plan view showing an example of an arrangement of a plurality of nanostructures in a nano-photonic lens array according to another embodiment;

FIG. 8 is a plan view showing an example of an arrangement of a plurality of nanostructures in a nano-photonic lens array, according to another embodiment;

FIGS. 9A and 9B are cross-sectional views schematically showing a configuration of a pixel array in an image sensor, according to another embodiment;

FIG. 10 is a diagram showing an example of a pixel arrangement in a pixel array of an image sensor, according to another embodiment;

FIG. 11 is a plan view schematically showing a sensor substrate in the pixel array shown in FIG. 10;

FIG. 12 is a plan view showing an example of an arrangement of a plurality of nanostructures of a nano-photonic lens array to which the pixel array shown in FIG. 10 may be applied;

FIG. 13 is a diagram showing an example of a phase profile of green light passing through the nano-photonic lens array of FIG. 12;

FIG. 14 is a plan view showing an example of an arrangement of a plurality of nanostructures in a nano-photonic lens array, according to another embodiment;

FIG. 15 is a block diagram of an electronic apparatus including an image sensor, according to an embodiment;

FIG. 16 is a block diagram schematically showing a camera module of FIG. 15;

FIG. 17 is a block diagram of an electronic apparatus including a multi-camera module; and

FIG. 18 is a detailed block diagram of the multi-camera module in the electronic apparatus of FIG. 17.

### DETAILED DESCRIPTION

Reference will now be made in detail to one or more embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

As used herein, the term “and/or” includes any and all combinations of one or more of the associated listed items. Expressions such as “at least one of,” when preceding a list of elements, modify the entire list of elements and do not modify the individual elements of the list. Expressions such as “at least one of a, b or c” and “at least one of a, b and c” indicate “only a,” “only b,” “only c,” “both a and b,” “both a and c,” “both b and c,” and “all of a, b, and c.”

Hereinafter, an image sensor including a nano-photonic lens array and an electronic apparatus including the image sensor will be described in detail with reference to accompanying drawings. The embodiments of the disclosure are capable of various modifications and may be embodied in many different forms. In the drawings, like reference numerals denote like components, and sizes of components in the drawings may be exaggerated for convenience of explanation.

When a layer, a film, a region, or a panel is referred to as being “on” another element, it may be directly on/under/at left/right sides of the other layer or substrate, or intervening layers may also be present.

It will be understood that although the terms “first,” “second,” etc. may be used herein to describe various components, these components should not be limited by these terms. These components are only used to distinguish one component from another. These terms do not limit that materials or structures of components are different from one another.

An expression used in the singular encompasses the expression of the plural, unless it has a clearly different meaning in the context. It will be further understood that when a portion is referred to as “comprising” another component, the portion may not exclude another component but may further comprise another component unless the context states otherwise.

In addition, the terms such as “ . . . unit”, “module”, etc. provided herein indicates a unit performing a function or operation, and may be implemented by hardware, software, or a combination of hardware and software.

The use of the terms of “the above-described” and similar indicative terms may correspond to both the singular forms and the plural forms.

Also, operations of all methods described herein may be performed in any suitable order unless otherwise indicated herein or otherwise clearly contradicted by context. Also, the use of all exemplary terms (for example, etc.) is only to describe a technical spirit in detail, and the scope of rights is not limited by these terms unless the context is limited by the claims.

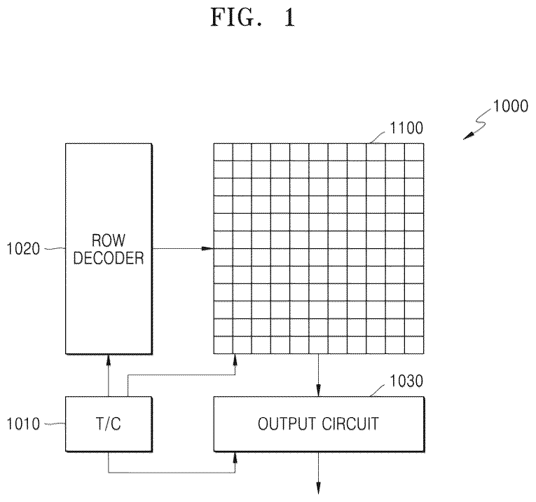

FIG. 1 is a schematic block diagram of an image sensor according to an embodiment. Referring to FIG. 1, an image sensor 1000 may include a pixel array 1100, a timing controller 1010, a row decoder 1020, and an output circuit 1030. The image sensor 1000 may be a charge-coupled device (CCD) image sensor or a complementary metal oxide semiconductor (CMOS) image sensor.

The pixel array 1100 includes pixels that are two-dimensionally arranged in a plurality of rows and columns. The row decoder 1020 selects one of the rows in the pixel array 1100 in response to a row address signal output from the timing controller 1010. The output circuit 1030 outputs a photosensitive signal, in a line unit, from a plurality of pixels arranged in the selected row. To this end, the output circuit 1030 may include a column decoder and an analog-to-digital converter (ADC). For example, the output circuit 1030 may include a plurality of ADCs that are disposed respectively to columns between the column decoder and the pixel array 1100, or one ADC disposed at an output end of the column decoder. The timing controller 1010, the row decoder 1020, and the output circuit 1030 may be implemented as one chip or in separate chips. A processor for processing an image signal output from the output circuit 1030 may be implemented as one chip with the timing controller 1010, the row decoder 1020, and the output circuit 1030.

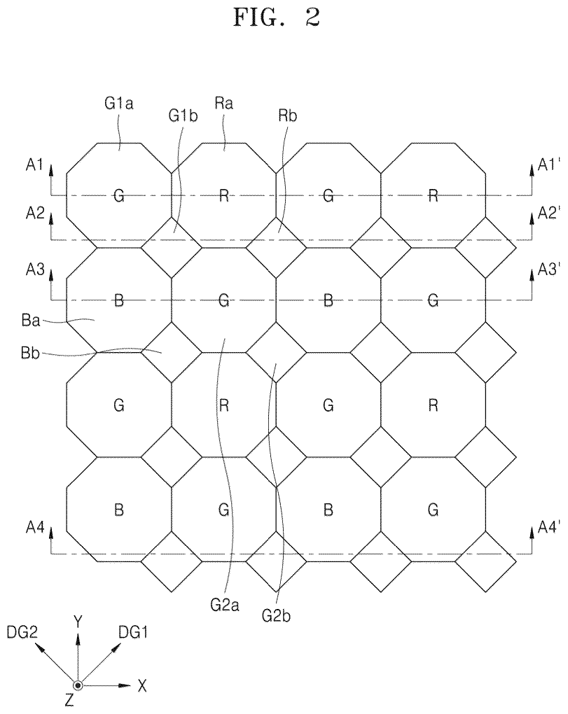

The pixel array 1100 may include a plurality of pixels that sense light of different wavelengths. The pixel arrangement may be implemented in various ways. For example, FIG. 2 is a diagram showing an example of a pixel arrangement in the pixel array 1100 of the image sensor 1000 according to an embodiment. Referring to FIG. 2, the pixel array 1100 may include main pixels based on a Bayer pattern structure generally adopted in an image sensor and corner pixels between the main pixels.

The main pixels may include a red main pixel Ra, a first green main pixel G1a, a blue main pixel Ba, and a second green main pixel G2a disposed in first to fourth quadrants, respectively, in a unit pixel pattern of a 2×2 array. In the unit pixel pattern, the red main pixel Ra and the blue main pixel Ba may be arranged in a first diagonal direction DG1, and the first green main pixel Gla and the second green main pixel G2a may be arranged in a second diagonal direction DG2 crossing the first diagonal direction DG1. The pixel array 1100 may include a plurality of unit pixel patterns that are two-dimensionally arranged. Therefore, with regard to the overall arrangement of the main pixels, a first row in which a plurality of first green main pixels G1a and a plurality of red main pixels Ra are alternately arranged in a first direction (i.e., X direction), and a second row in which a plurality of blue main pixels Ba and a plurality of second green main pixels G2a are alternately arranged in the first direction are repeatedly arranged in a second direction (i.e., Y direction) perpendicular to the first direction. The first direction and the second direction may be directions in which the pixel array 1100 extends on a plane. For example, one side of the pixel array 1100 may extend in the first direction, and the other side may extend in the second direction. The first diagonal direction DG1 and the second diagonal direction DG2 may be directions between the first direction and the second direction.

The corner pixels may be disposed to be in contact with vertices of the corresponding main pixels in the second diagonal direction DG2. For example, the corner pixels may include a first green corner pixel G1b disposed to contact the vertex of the first green main pixel Gla in the second diagonal direction DG2, a red corner pixel Rb disposed to contact the vertex of the red main pixel Ra in the second diagonal direction DG2, a blue corner pixel Bb disposed to contact the vertex of the blue main pixel Ba in the second diagonal direction DG2, and a second green corner pixel G2b disposed to contact the vertex of the second green main pixel G2a in the second diagonal direction DG2. Each of the first green corner pixel G1b, the red corner pixel Rb, the blue corner pixel Bb, and second green corner pixel G2b may be surrounded by and in contact with their four adjacent main pixels. For example, the first green corner pixel G1b may be surrounded and in contact with the first green main pixel G1a, the red main pixel Ra, the blue main pixel Ba, and the second green main pixel G2a. When considering only the corner pixels, a plurality of first green corner pixels G1b and a plurality of red corner pixels Rb are alternately arranged in the first direction, and a plurality of blue corner pixels Bb and a plurality of second green corner pixels G2b are alternately arranged in the first direction on another cross-section in the second direction.

With regard to the overall arrangement of pixels of the pixel array 1100, the first green main pixel G1a, the first green corner pixel G1b, the second green main pixel G2a, and the second green corner pixel G2b may be alternately arranged along one cross-section in the second diagonal direction DG2. Therefore, only green pixels may be arranged on one cross-section in the second diagonal direction DG2. The first green corner pixel G1b may be disposed between the first green main pixel G1a and the second green main pixel G2a in the second diagonal direction DG2, and the second green corner pixel G2b may be disposed between the second green main pixel G2a and the first green main pixel Gla in the second diagonal direction DG2. In addition, the red main pixel Ra, the red corner pixel Rb, the blue main pixel Ba, and the blue corner pixel Bb may be alternately arranged on another cross-section in the second diagonal direction DG2. The red corner pixel Rb may be disposed between the red main pixel Ra and the blue main pixel Ba in the second diagonal direction DG2, and the blue corner pixel Bb may be disposed between the blue main pixel Ba and the red main pixel Ra in the second diagonal direction DG2.

In addition, the first green main pixel G1a, the red corner pixel Rb, the second green main pixel G2a, and the blue corner pixel Bb may be alternately arranged along one section in the first diagonal direction DG1. Therefore, the red corner pixel Rb and the blue corner pixel Bb may be disposed between two green main pixels in the first diagonal direction DG1. The red main pixel Ra, the first green corner pixel G1b, the blue main pixel Ba, and the second green corner pixel G2b may be alternately arranged along another cross-section in the first diagonal direction DG1. Accordingly, the first green corner pixel G1b and the second green corner pixel G2b may be disposed between the red main pixel Ra and the blue main pixel Ba in the first diagonal direction DG1.

The size (e.g., a width or a length of one side) of the main pixels may be three times or more larger than that of the corner pixels. For example, the width of the main pixels may be about 3 μm or more and the width of the corner pixels may be about 1 μm or less. Therefore, because the light-receiving area of the main pixels is larger than the light-receiving area of the corner pixels, the sensitivity of the main pixels may be higher than that of the corner pixels. The image sensor 1000 including the pixel array 1100 having such a pixel array may be, for example, a high dynamic range (HDR) image sensor. In this case, in a low illuminance environment, an image may be generated mainly using signals output from the main pixels, and in a high illuminance environment, an image may be generated using signals output from both the main pixels and the corner pixels. Therefore, a contrast ratio of the image may be greatly improved by using the main pixels having relatively high sensitivity and the corner pixels having relatively low sensitivity.

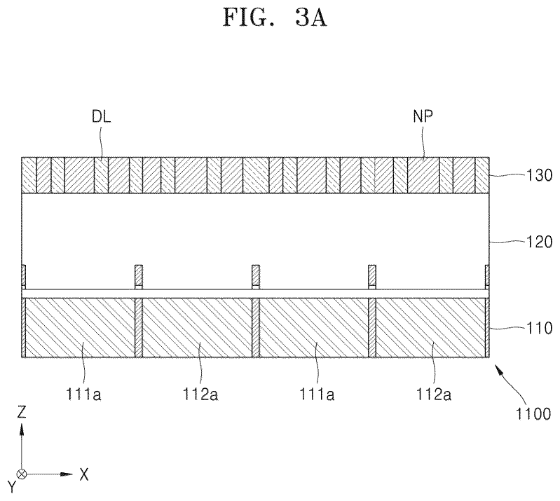

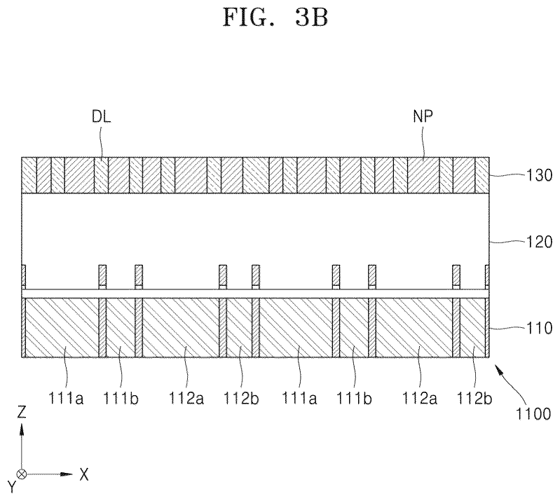

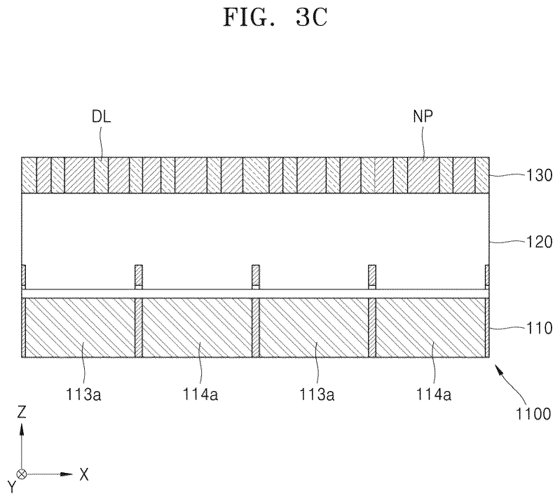

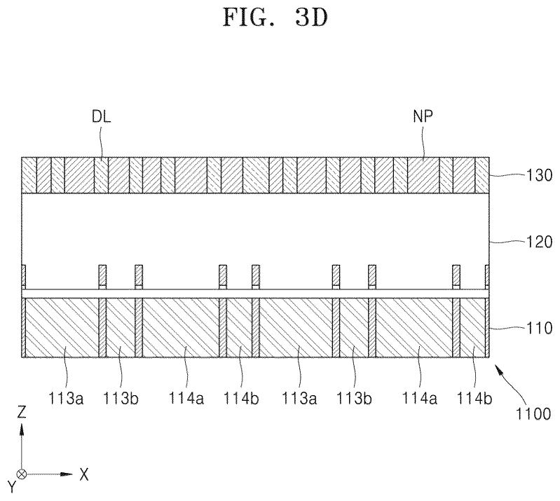

FIGS. 3A to 3D are cross-sectional views schematically showing a configuration of the pixel array 1100 of the image sensor 1000 according to an embodiment. Particularly, FIG. 3A is a cross-sectional view taken along line A1-A1′ of FIG. 2, FIG. 3B is a cross-sectional view taken along line A2-A2′ of FIG. 2, FIG. 3C is a cross-sectional view taken along line A3-A3′ of FIG. 2, and FIG. 3D is a cross-sectional view taken along line A4-A4′ of FIG. 2. Referring to FIGS. 3A to 3D, the pixel array 1100 may include a sensor substrate 110, a spacer layer 120 disposed on the sensor substrate 110, and a nano-photonic lens array 130 disposed on the spacer layer 120.

The sensor substrate 110 may include a plurality of light sensing devices that sense incident light. For example, in the A1-A1′ cross-section of FIG. 2, the sensor substrate 110 may include a plurality of first main light sensing devices 111a and a plurality of second main light sensing devices 112a alternately arranged in a first direction. In the A2-A2′ cross-section of FIG. 2, the sensor substrate 110 may include the plurality of first main light sensing devices 111a, a plurality of first corner light sensing devices 111b, the plurality of second main light sensing devices 112a, and a plurality of second corner light sensing devices 112b alternately arranged in the first direction. In the A3-A3′ cross-section of FIG. 2, the sensor substrate 110 may include a plurality of third main light sensing devices 113a and a plurality of fourth main light sensing devices 114a alternately arranged in the first direction. In the A4-A4′ cross-section of FIG. 2, the sensor substrate 110 may include the plurality of third main light sensing devices 113a, a plurality of third corner light sensing devices 113b, the plurality of fourth main light sensing devices 114a, and a plurality of fourth corner light sensing devices 114b alternately arranged in the first direction.

The first main light sensing device 111a may correspond to the first green main pixel G1a. The first corner light sensing device 111b may correspond to the first green corner pixel G1b. The second main light sensing device 112a may correspond to the red main pixel Ra. The second corner light sensing device 112b may correspond to the red corner pixel Rb. The third main light sensing device 113a may correspond to the blue main pixel Ba. The third corner light sensing device 113b may correspond to the blue corner pixel Bb. The fourth main light sensing device 114a may correspond to the second green main pixel G2a. And, the fourth corner light sensing device 114b may correspond to the second green corner pixel G2b. Accordingly, descriptions of the arrangement relationships between the first green main pixel G1a, the first green corner pixel G1b, the red main pixel Ra, the red corner pixel Rb, the blue main pixel Ba, the blue corner pixel Bb, the second green main pixel G2a, and the second green corner pixel G2b may also be applied to the arrangement relationships between the first main light sensing device 111a, the first corner light sensing device 111b, the second main light sensing device 112a, the second corner light sensing device 112b, the third main light sensing device 113a, the third corner light sensing device 113b, the fourth main light sensing device 114a, and the fourth corner light sensing device 114b.

For example, the sensor substrate 110 may include a plurality of unit patterns two-dimensionally arranged in the first direction and second direction, and each unit pattern may include the first main light sensing device 111a, the second main light sensing device 112a, the third main light sensing device 113a, and the fourth main light sensing device 114a which are arranged in a 2×2 array. In addition, each unit pattern may include the first corner light sensing device 111b disposed to contact the vertex of the first main light sensing device 111a in the second diagonal direction DG2, the second corner light sensing device 112b disposed to contact the vertex of the second main light sensing device 112a in the second diagonal direction DG2, the third corner light sensing device 113b disposed to contact the vertex of the third main light sensing device 113a in the second diagonal direction DG2, and the fourth corner light sensing device 114b disposed to contact the vertex of the fourth main light sensing device 114a in the second diagonal direction DG2. In addition, the first main light sensing device 111a may be larger than the first corner light sensing device 111b, the second main light sensing device 112a may be larger than the second corner light sensing device 112b, the third main light sensing device 113a may be larger than the third corner light sensing device 113b, and the fourth main light sensing device 114a may be larger than the fourth corner light sensing device 114b.

The spacer layer 120 is disposed between the sensor substrate 110 and the nano-photonic lens array 130 to maintain a constant distance between the sensor substrate 110 and the nano-photonic lens array 130. The spacer layer 120 may include a material that is transparent to visible light, for example, a dielectric material that has a lower refractive index than nanostructures NP described below and has a lower absorption rate in a visible light band, such as poly methyl methacrylate (PMMA), siloxane-based glass (SOG), SiO₂, Si₃N₄, Al₂O₃, etc.

The nano-photonic lens array 130 may be provided on the spacer layer 120. According to an embodiment, the nano-photonic lens array 130 may be configured to color-separate incident light. For example, the nano-photonic lens array 130 may separate incident light into light (e.g., green light) of a first wavelength band, light (e.g., red light) of a second wavelength band different from the first wavelength band, and light (e.g., blue light) of a third wavelength band different from the first wavelength band and the second wavelength band and allow the separated light to proceed in different passages. In addition, the nano-photonic lens array 130 may also be configured to serve as a lens that focuses the color-separated light of the first wavelength band, the second wavelength band, and the third wavelength band respectively to light sensing devices corresponding to the color-separated light of the first wavelength band, the second wavelength band, and the third wavelength band. For example, the nano-photonic lens array 130 may be configured to: separate the light of the first wavelength band from the incident light and focus the separated light onto each of the first main light sensing device 111a, the first corner light sensing device 111b, the fourth main light sensing device 114a, and the fourth corner light sensing device 114b; to separate the light of the second wavelength band from the incident light and focus the separated light onto each of the second main light sensing device 112a and the second corner light sensing device 112b; and separate the light of the third wavelength band from the incident light and focus the separated light onto each of third main light sensing device 113a and the third corner light sensing device 113b.

To this end, the nano-photonic lens array 130 may include a plurality of nanostructures NP arranged according to a certain rule. In addition, the nano-photonic lens array 130 may further include a dielectric layer DL filled between the plurality of nanostructures NP. In order for the nano-photonic lens array 130 to perform the above-described function, the plurality of nanostructures NP of the nano-photonic lens array 130 may be variously configured. For example, the plurality of nanostructures NP may be arranged to differently change a phase of transmitted light transmitting through the nano-photonic lens array 130 according to a position on the nano-photonic lens array 130. A phase profile of transmitted light implemented by the nano-photonic lens array 130 may be determined according to the cross-sectional size (e.g., width or diameter), cross-sectional shape, and height of each of the nanostructures NP, the arrangement period (or pitch), and arrangement shape of the plurality of nanostructures NP. In addition, the behavior of the light transmitted through the nano-photonic lens array 130 may be determined according to the phase profile of the transmitted light.

The nanostructure NP may have a size that is less than a wavelength of visible light. The nanostructures NP may have a size that is less than, for example, the blue wavelength. For example, the cross-sectional width (or diameter) of the nanostructure NP may be less than 400 nm, 300 nm, or 200 nm and greater than about 80 nm. The height of the nanostructure NP may be about 500 nm to about 1500 nm, and may be greater than the cross-sectional width of the nanostructure NP.

The nanostructure NP may include a material having a relatively high refractive index compared to a peripheral material and a relatively low absorption rate in the visible light band. For example, the nanostructure NP may include c-Si, p-Si, a-Si and a Group III-V compound semiconductor (GaP, GaN, GaAs etc.), SiC, TiO₂, SiN₃, ZnS, ZnSe, Si₃N₄, and/or a combination thereof. The periphery of the nanostructure NP may be filled with the dielectric layer DL having a relatively low refractive index as compared to that of the nanostructure NP and having a relatively low absorption rate in the visible light band. For example, the dielectric layer DL may be filled with PMMA, SOG, SiO₂, Si₃N₄, Al₂O₃, air, etc.

The refractive index of the nanostructure NP may be about 2.0 or greater with respect to light of about a 630 nm wavelength, and the refractive index of the dielectric layer DL may be about 1.0 to about 2.0 or less with respect to the light of about the 630 nm wavelength. Also, a difference between the refractive index of the nanostructure NP and the refractive index of the dielectric layer DL may be about 0.5 or more. The nanostructure NP having a difference in a refractive index between the refractive index of the peripheral material may change a phase of light passing through the nanostructure NP. This is caused by phase delay that occurs due to the shape dimension of a sub-wavelength of the nanostructure NP, and a degree to which the phase is delayed may be determined by a detailed shape dimension and arrangement shape of the nanostructure NP.

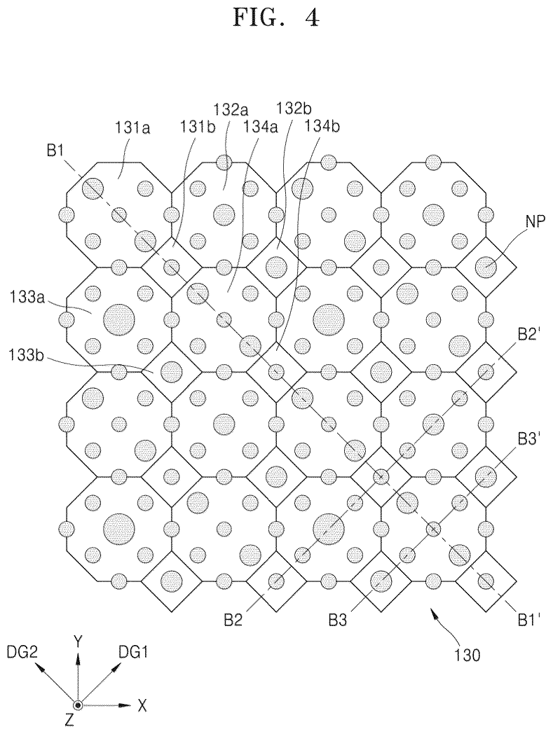

FIG. 4 is a plan view showing an example of an arrangement of the plurality of nanostructures NP in the nano-photonic lens array 130 shown in FIGS. 3A to 3D. Referring to FIG. 4, the nano-photonic lens array 130 may include a plurality of meta regions respectively corresponding to a plurality of light sensing devices of the sensor substrate 110. For example, the nano-photonic lens array 130 may include a plurality of first main meta regions 131a respectively corresponding to the plurality of first main light sensing devices 111a, a plurality of first corner meta regions 131b respectively corresponding to the plurality of first corner light sensing devices 111b, a plurality of second main meta regions 132a respectively corresponding to the plurality of second main light sensing devices 112a, a plurality of second corner meta regions 132b respectively corresponding to the plurality of second corner light sensing devices 112b, a plurality of third main meta regions 133a respectively corresponding to the plurality of third main light sensing devices 113a, a plurality of third corner meta regions 133b respectively corresponding to the plurality of third corner light sensing devices 113b, a plurality of fourth main meta regions 134a respectively corresponding to the plurality of fourth main light sensing devices 114a, and a plurality of fourth corner meta regions 134b respectively corresponding to the plurality of fourth corner light sensing devices 114b.

One first main meta region 131a, one first corner meta region 131b, one second main meta region 132a, one second corner meta region 132b, one third main meta region 133a, one third corner meta region 133b, one fourth main meta region 134a, and one fourth corner meta region 134b which are grouped and arranged may form a unit meta pattern. The first main meta region 131a, the first corner meta region 131b, the second main meta region 132a, the second corner meta region 132b, the third main meta region 133a, the third corner meta region 133b, the fourth main meta region 134a, and the fourth corner meta region 134b may be disposed to face the first main light sensing device 111a, the first corner light sensing device 111b, the second main light sensing device 112a, the second corner light sensing device 112b, the third main light sensing device 113a, the third corner light sensing device 113b, the fourth main light sensing device 114a, and the fourth corner light sensing device 114b respectively corresponding thereto in a third direction (Z direction) perpendicular to the first direction and the second direction.

Accordingly, the arrangement of the first main meta region 131a, the first corner meta region 131b, the second main meta region 132a, the second corner meta region 132b, the third main meta region 133a, the third corner meta region 133b, the fourth main meta region 134a, and the fourth corner meta region 134b in the unit meta pattern may be the same as positions of the first main light sensing device 111a, the first corner light sensing device 111b, the second main light sensing device 112a, the second corner light sensing device 112b, the third main light sensing device 113a, the third corner light sensing device 113b, the fourth main light sensing device 114a, and the fourth corner light sensing device 114b respectively corresponding thereto in the unit pixel pattern. In addition, the first main meta region 131a may be larger than the first corner meta region 131b, the second main meta region 132a may be larger than the second corner meta region 132b, the third main meta region 133a may be larger than the third corner meta region 133b, and the fourth main meta region 134a may be larger than the fourth corner meta region 134b.

Each of the first main meta region 131a, the second main meta region 132a, the third main meta region 133a, and the fourth main meta region 134a may include the plurality of nanostructures NP having different cross-sectional areas. Each of the first corner meta region 131b, the second corner meta region 132b, the third corner meta region 133b, and the fourth corner meta region 134b may include at least one nanostructure NP. FIG. 4 shows that only one nanostructure NP is disposed in each of the first corner meta region 131b, the second corner meta region 132b, the third corner meta region 133b, and the fourth corner meta region 134b, but two or more nanostructures NP may be disposed. Even in this case, the number of nanostructures NP disposed in the first main meta region 131a may be greater than the number of nanostructures NP disposed in the first corner meta region 131b. Likewise, the number of nanostructures NP disposed in each of the second main meta region 132a, the third main meta region 133a, and the fourth main meta region 134a may be respectively greater than the number of nanostructures NP disposed in each of the second corner meta region 132b, the third corner meta region 133b, and the fourth corner meta region 134b.

Materials, cross-sectional shapes, and heights of the plurality of nanostructures NP in the entire region of the nano-photonic lens array 130 may be the same, and only cross-sectional areas of the plurality of nanostructures NP may be different from each other. FIG. 4 shows that the plurality of nanostructures NP have a circular cross-section on a plane parallel to the first direction and the second direction, that is, the plurality of nanostructures NP have a cylindrical shape, but the disclosure is not limited thereto. The plurality of nanostructures NP on a plane defined by the first direction and the second direction may have a polygonal cross-section such as a circular cross-section, an elliptical cross-section, or a rectangular cross-section. Hereinafter, the cross-sectional area of each of the nanostructures NP may be defined as the area of a cross-section of the nanostructure NP along the plane defined by the first direction and the second direction.

The positions and cross-sectional areas of the plurality of nanostructures NP may be configured to cause the light in the first wavelength band in the incident light incident on the nano-photonic lens array 130 to be focused onto each of the first main light sensing device 111a, the first corner light sensing device 111b, the fourth main light sensing device 114a, and the fourth corner light sensing device 114b, to cause the light in the second wavelength band to be focused onto each of the second main light sensing device 112a and the second corner light sensing device 112b, and to cause the light in the third wavelength band to be focused onto each of the third main light sensing device 113a and the third corner light sensing device 113b. For example, the first main meta region 131a and the fourth main meta region 134a may be configured to transmit the light in the second wavelength band to the second corner light sensing device 112b in the first diagonal direction DG1, and to transmit the light in the third wavelength band to the third corner light sensing device 113b in the first diagonal direction DG1. The first corner meta region 131b and the fourth corner meta region 134b may be configured to transmit the light in the second wavelength band to the second main light sensing device 112a in the first diagonal direction DG1, and to transmit the light in the third wavelength band to the third main light sensing device 113a in the first diagonal direction DG1. In addition, the second main meta region 132a and the third main meta region 133a may be configured to transmit the light in the first wavelength band to the first corner light sensing device 111b and the fourth corner light sensing device 114b in the first diagonal direction DG1, and the second corner meta region 132b and the third corner meta region 133b may be configured to transmit the light in the first wavelength band to the first main light sensing device 111a and the fourth main light sensing device 114a in the first diagonal direction DG1.

In particular, the positions and cross-sectional areas of the plurality of nanostructures NP may be configured to cause light in the same wavelength to be focused onto two of a plurality of light sensing devices in a diagonal direction, and the light of the same wavelength focused onto the two light sensing devices in the diagonal direction may have different intensities. For example, the positions and cross-sectional areas of the plurality of nanostructures NP may be configured to cause the intensity of light in the first wavelength band focused onto each of the first main light sensing device 111a and the first corner light sensing device 111b in contact with the second diagonal direction DG2 to be different, the intensity of light in the first wavelength band focused onto each of the fourth main light sensing device 114a and the fourth corner light sensing device 114b in contact with the second diagonal direction DG2 to be different, the intensity of light in the second wavelength band focused onto each of the second main light sensing device 112a and the second corner light sensing device 112b in contact with the second diagonal direction DG2 to be different, and the intensity of light in the third wavelength band focused onto each of the third main light sensing device 113a and the third corner light sensing device 113b in contact with the second diagonal direction DG2 to be different. In particular, the positions and cross-sectional areas of the plurality of nanostructures NP may be configured to cause the intensity of light in the first wavelength band focused onto the first main light sensing device 111a to be greater than the intensity of light in the first wavelength band focused onto the first corner light sensing device 111b, the intensity of light in the second wavelength band focused onto the second main light sensing device 112a to be greater than the intensity of light in the second wavelength band focused onto the second corner light sensing device 112b, the intensity of light in the third wavelength band focused onto the third main light sensing device 113a to be greater than the intensity of light in the third wavelength band focused onto the third corner light sensing device 113b, and the intensity of light in the first wavelength band focused onto the fourth main light sensing device 114a to be greater than the intensity of light in the first wavelength band focused onto the fourth corner light sensing device 114b.

To this end, distributions of the cross-sectional areas of the nanostructures NP in the first main meta region 131a, the first corner meta region 131b, the fourth main meta region 134a, and the fourth corner meta region 134b may be symmetrical with respect to lines extending in the first diagonal direction DG1 and the second diagonal direction DG2 which pass through the centers of the first main meta region 131a, the first corner meta region 131b, the fourth main meta region 134a, and the fourth corner meta region 134b. On the other hand, distributions of the cross-sectional areas of the nanostructures NP in the first main meta region 131a and the fourth main meta region 134a may be asymmetrical with respect to lines extending in the first direction and the second direction which pass through the centers of the first main meta region 131a and the fourth main meta region 134a. In addition, distributions of the cross-sectional areas of the nanostructures NP in the first main meta region 131a and the fourth main meta region 134a may be the same, and distributions of the cross-sectional areas of the nanostructures NP in the first corner meta region 131b and the fourth corner meta region 134b may be the same.

The distributions of the cross-sectional areas of the nanostructures NP in the second main meta region 132a, the second corner meta region 132b, the third main meta region 133a, and the third corner meta region 133b may be symmetrical with respect to lines extending in the first direction, the second direction, the first diagonal direction DG1, and the second diagonal direction DG2 which pass through the centers of the second main meta region 132a, the second corner meta region 132b, the third main meta region 133a, and the third corner meta region 133b. In addition, the distributions of the cross-sectional areas of the nanostructures NP in the second main meta region 132a and the third main meta region 133a may be different from each other. The distributions of the cross-sectional areas of the nanostructures NP in the second corner meta region 132b and the third corner meta region 133b may be the same or different from each other.

For example, the nanostructures NP may be disposed at the centers of the first main meta region 131a, the second main meta region 132a, the third main meta region 133a, and the fourth main meta region 134a. The cross-sectional areas of the nanostructures NP disposed at the centers of the first main meta region 131a and the fourth main meta region 134a may be the same. The cross-sectional areas of the nanostructures NP disposed at the centers of the first main meta region 131a, the second main meta region 132a, and the third main meta region 133a may be different from each other.

In addition, two nanostructures NP disposed to face each other in the first diagonal direction DG1 and two nanostructures NP disposed to face each other in the second diagonal direction DG2 with respect to the central nanostructure NP may be further provided in the first main meta region 131a, the second main meta region 132a, the third main meta region 133a, and the fourth main meta region 134a. In the first main meta region 131a and the fourth main meta region 134a, cross-sectional areas of the two nanostructures NP disposed to face each other in the first diagonal direction DG1 are the same, and cross-sectional areas of the two nanostructures NP disposed to face each other in the second diagonal direction DG2 are the same. On the other hand, in the first main meta region 131a and the fourth main meta region 134a, the cross-sectional areas of the two nanostructures NP disposed to face each other in the first diagonal direction DG1 may be different from the cross-sectional areas of the two nanostructures NP disposed to face each other in the second diagonal direction DG2. In the second main meta region 132a and the third main meta region 133a, the cross-sectional areas of the two nanostructures NP disposed to face each other in the first diagonal direction DG1 may be the same as the cross-sectional areas of the two nanostructures NP disposed to face each other in the second diagonal direction DG2.

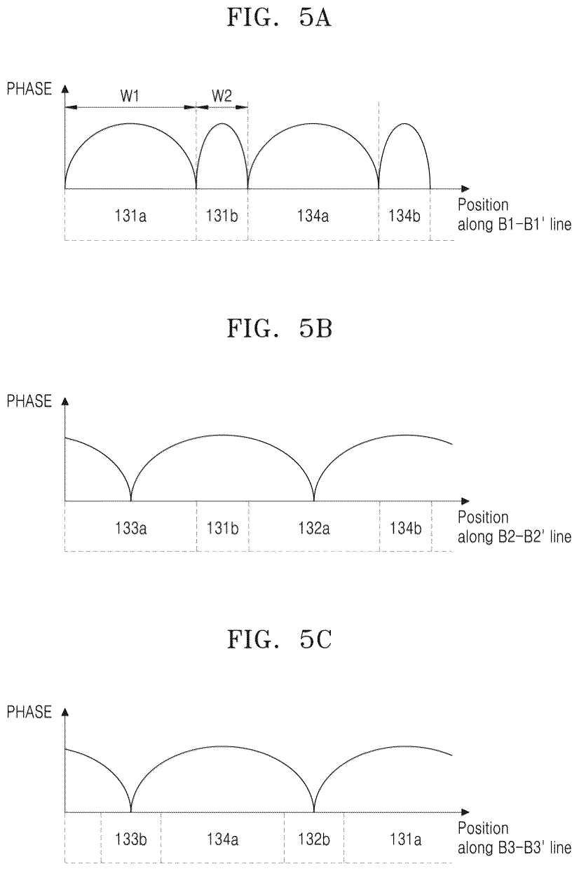

FIGS. 5A to 5C are diagrams showing examples of a phase profile of green light passing through the nano-photonic lens array 130 shown in FIG. 4. In particular, FIG. 5A shows the phase profile of green light in a cross-section of the nano-photonic lens array 130 along a B1-B1′ line in the second diagonal direction DG2, FIG. 5B shows the phase profile of green light in a cross-section of the nano-photonic lens array 130 along a B2-B2′ line in the first diagonal direction DG1, and FIG. 5C shows the phase profile of green light in a cross-section of the nano-photonic lens array 130 along a B3-B3′ line in the first diagonal direction DG1.

Referring to FIG. 5A, on the cross-section in the second diagonal direction DG2 passing through the centers of the first main meta region 131a, the first corner meta region 131b, the fourth main meta region 134a, and the fourth corner meta region 134b, the green light immediately after passing through the nano-photonic lens array 130, that is, on a lower surface of the nano-photonic lens array 130, may have the phase profile that is the largest in the center of each of the first main meta region 131a, the first corner meta region 131b, the fourth main meta region 134a, and the fourth corner meta region 134b and is reduced in the direction away from each center. In particular, the phase profile of green light may be the smallest at a boundary between the first main meta region 131a, the first corner meta region 131b, the fourth main meta region 134a, and the fourth corner meta region 134b. In addition, a width of the phase profile of green light commonly formed by the first main meta region 131a, the first corner meta region 131b, the fourth main meta region 134a, and the fourth corner meta region 134b may be the same as a width of the first main meta region 131a, the first corner meta region 131b, the fourth main meta region 134a, and the fourth corner meta region 134b in the second diagonal direction DG2. For example, a first width W1 of the phase profile of green light formed at positions corresponding to the first main meta region 131a and the fourth main meta region 134a may be greater than a second width W2 of the phase profile of green light formed at positions corresponding to the first corner meta region 131b and the fourth corner meta region 134b.

Referring to FIG. 5B, on the cross-section in the first diagonal direction DG1 passing through the centers of the third main meta region 133a, the first corner meta region 131b, the second main meta region 132a, and the fourth corner meta region 134b, the green light immediately after passing through the nano-photonic lens array 130 may have the phase profile that is the largest in the center of each of the first corner meta region 131b and the fourth corner meta region 134b and is reduced in the direction away from each center. In addition, the phase profile of green light may be the smallest at the center of each of the third main meta region 133a and the second main meta region 132a. Accordingly, a width of the phase profile of green light commonly formed by the third main meta region 133a, the first corner meta region 131b, the second main meta region 132a, and the fourth corner meta region 134b may be greater than a width of each of the first corner meta region 131b and the fourth corner meta region 134b in the first diagonal direction DG1.

Referring to FIG. 5C, on the cross-section in the first diagonal direction DG1 passing through the centers of the third corner meta region 133b, the first main meta region 131a, the second corner meta region 132b, and the fourth main meta region 134a, the green light immediately after passing through the nano-photonic lens array 130 may have the phase profile that is the largest in the center of each of the first main meta region 131a and the fourth main meta region 134a and is reduced in the direction away from each center. In addition, the phase profile of green light may be the smallest at the center of each of the third corner meta region 133b and the second corner meta region 132b. Accordingly, a width of the phase profile of green light commonly formed by the third corner meta region 133b, the first main meta region 131a, the second corner meta region 132b, and the fourth main meta region 134a in the first diagonal direction DG1 may be greater than a width of each of the first main meta region 131a and the fourth main meta region 134a in the first diagonal direction DG1.

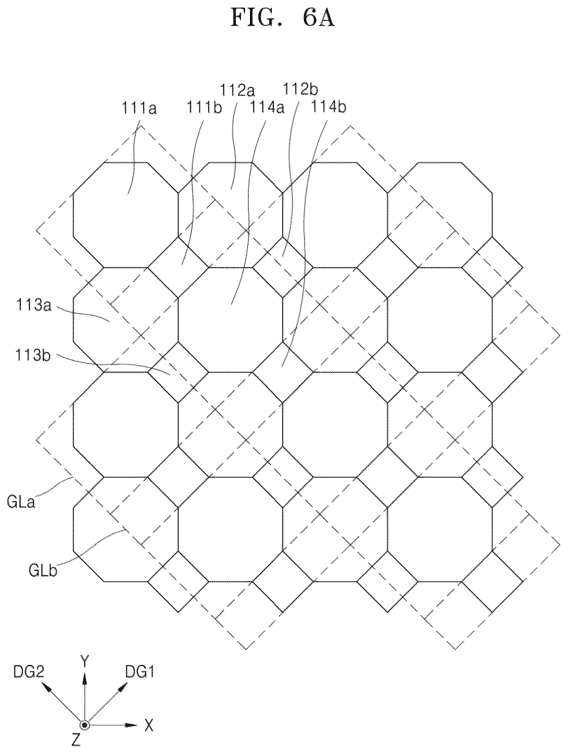

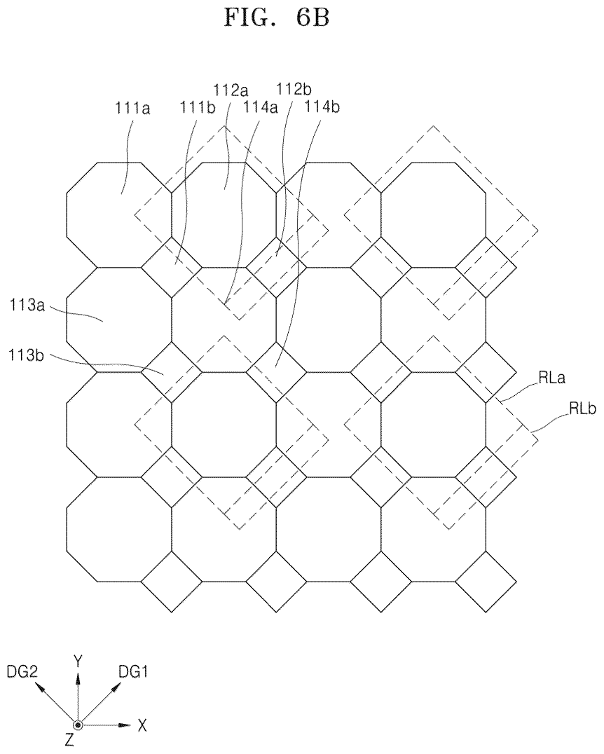

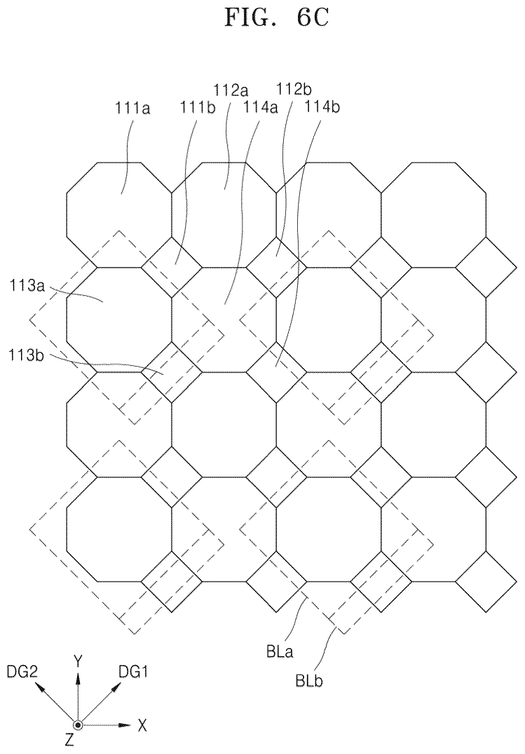

FIG. 6A is a diagram showing an example of an array of green light focusing regions formed by the nano-photonic lens array 130, FIG. 6B is a diagram showing an example of an array of red light focusing regions formed by the nano-photonic lens array 130, and FIG. 6C is a diagram showing an example of an array of blue light focusing regions formed by the nano-photonic lens array 130.

Referring to FIG. 6A, the array of the green light focusing regions formed by the nano-photonic lens array 130 may include a plurality of main green light focusing regions GLa and a plurality of corner green light focusing regions GLb. In light incident on the nano-photonic lens array 130, green light passing through each of the main green light focusing regions GLa may be focused onto the corresponding first main light sensing device 111a or the corresponding fourth main light sensing device 114a, and green light passing through each of the corner green light focusing regions GLb may be focused onto the corresponding first corner light sensing device 111b or the corresponding fourth corner light sensing device 114b. The plurality of main green light focusing regions GLa may be continuously arranged in the first diagonal direction DG1, and the plurality of corner green light focusing regions GLb may be continuously arranged in the first diagonal direction DG1. In addition, the plurality of main green light focusing regions GLa and the plurality of corner green light focusing regions GLb may be alternately arranged one by one in the second diagonal direction DG2.

In the first diagonal direction DG1, a width of each of the main green light focusing regions GLa may be greater than a width of the corresponding first main light sensing device 111a and a width of the corresponding fourth main light sensing device 114a, and a width of each of the corner green light focusing regions GLb may be greater than a width of the corresponding first corner light sensing device 111b and a width of the corresponding fourth corner light sensing device 114b. In the second diagonal direction DG2, the width of each of the main green light focusing regions GLa may be the same as the width of the corresponding first main light sensing device 111a or the width of the corresponding fourth main light sensing device 114a, and the width of each of the corner green light focusing regions GLb may be the same as the width of the corresponding first corner light sensing device 111b or the width of the corresponding fourth corner light sensing device 114b. Accordingly, the area of the main green light focusing regions GLa may be larger than the area of the corner green light focusing regions GLb.

Referring to FIG. 6B, the array of the red light focusing regions formed by the nano-photonic lens array 130 may include a plurality of main red light focusing regions RLa and a plurality of corner red light focusing regions RLb. In the light incident on the nano-photonic lens array 130, red light passing through each of the main red light focusing regions RLa may be focused onto the corresponding second main light sensing device 112a, and red light passing through each of the corner red light focusing regions RLb may be focused onto the corresponding second corner light sensing device 112b. A width of each of the main red light focusing regions RLa in the first diagonal direction DG1 may be greater than a width of the corresponding second main light sensing device 112a in the first diagonal direction DG1, and a width of each of the main red light focusing regions RLa in the second diagonal direction DG2 may be greater than a width of the corresponding second main light sensing device 112a in the second diagonal direction DG2. The width of each of the corner red light focusing regions RLb in the first diagonal direction DG1 may be greater than the width of the corresponding corner light sensing area 112b in the first diagonal direction DG1, and the width of each of the corner red light focusing regions RLb in the second diagonal direction DG2 may be less than the width of the corresponding corner light sensing area 112b in the second diagonal direction DG2. Accordingly, the area of the main red light focusing regions RLa may be larger than the area of the corner red light focusing regions RLb.

Referring to FIG. 6C, the array of the blue light focusing regions formed by the nano-photonic lens array 130 may include a plurality of main blue light focusing regions BLa and a plurality of corner blue light focusing regions BLb. In the light incident on the nano-photonic lens array 130, blue light passing through each of the main blue light focusing regions BLa may be focused onto the corresponding third main light sensing device 113a, and blue light passing through each of the corner blue light focusing regions BLb may be focused onto the corresponding third corner light sensing device 113b. A width of each of the main blue light focusing regions BLa in the first diagonal direction DG1 may be greater than a width of the corresponding third main light sensing device 113a in the first diagonal direction DG1, and a width of each of the main blue light focusing regions BLa in the second diagonal direction DG2 may be greater than a width of the corresponding third main light sensing device 113a in the second diagonal direction DG2. A width of each of the corner blue light focusing regions BLb in the first diagonal direction DG1 may be greater than a width of the corresponding third corner light sensing device 113b in the first diagonal direction DG1, and a width of each of the corner blue light focusing regions BLb in the second diagonal direction DG2 may be less than a width of the corresponding third corner light sensing device 113b in the second diagonal direction DG2. Accordingly, the area of the main blue light focusing regions BLa may be larger than the area of the corner blue light focusing regions BLb.

According to an embodiment, the light utilization efficiency of the image sensor 1000 may be improved by using the nano-photonic lens array 130 that performs both color separation and focusing functions. In addition, the nano-photonic lens array 130 according to the embodiment may be configured to color-separate and focus incident light onto two light sensing devices of the same color adjacent in a diagonal direction. For example, the nano-photonic lens array 130 may be configured to focus green light onto each of the first main light sensing device 111a and the first corner light sensing device 111b, and the fourth main light sensing device 114a and the fourth corner light sensing device 114b which are adjacent in the second diagonal direction DG2, to focus red light onto each of the second main light sensing device 112a and the second corner light sensing device 112b which are adjacent in the second diagonal direction DG2, and to focus blue light onto the third main light sensing device 113a and the third corner light sensing device 113b which are adjacent in the second diagonal direction DG2.

The nano-photonic lens array 130 according to the embodiment may color-separate and focus incident light to two adjacent light sensing devices of the same color at different focusing efficiencies so that two pixels of the same color adjacent in a diagonal direction may have different sensitivities. For example, the area of the main green light focusing region GLa is larger than the area of the corner green light focusing region GLb, the area of the main red light focusing region RLa is larger than the area of the corner red light focusing region RLb, and the area of the main blue light focusing region BLa is larger than the area of the corner blue light focusing region BLb. Therefore, the intensity of green light focused by the main green light focusing region GLa may be greater than the intensity of green light focused by the corner green light focusing region GLb, the intensity of red light focused by the main red light focusing region RLa may be greater than the intensity of red light focused by the corner red light focusing region RLb, and the intensity of blue light focused by the main blue light focusing region BLa may be greater than the intensity of blue light focused by the corner blue light focusing region BLb. The image sensor 1000 according to an embodiment may dynamically utilize pixels in a low illuminance environment and a high illuminance environment, and may be applied to, for example, a high dynamic range (HDR) sensor.

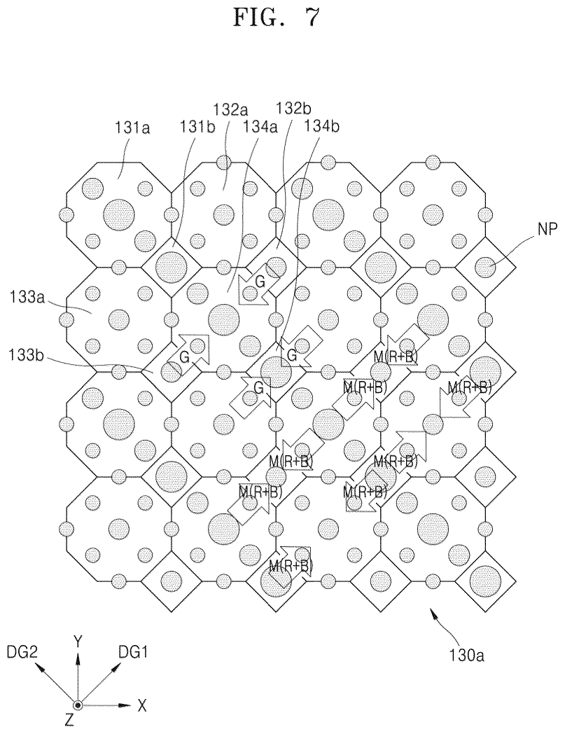

The arrangement of the nanostructures NP for implementing the above-described color separation and focusing functions of the nano-photonic lens array 130 is not limited to the example shown in FIG. 5, and various other arrangements of the nanostructures NP may be possible. FIG. 7 is a plan view showing an example of an arrangement of the plurality of nanostructures NP of a nano-photonic lens array 130a according to another embodiment. In comparison with FIG. 4, the arrangement of the nanostructures NP of the nano-photonic lens array 130a shown in FIG. 7 is similar to the arrangement form of the nanostructures NP of the nano-photonic lens array 130 shown in FIG. 4, and only some of the nanostructures NP may have different cross-sectional areas. For example, cross-sectional areas of the nanostructures NP disposed at the centers of the first main meta region 131a, the first corner meta region 131b, the second main meta region 132a, the second corner meta region 132b, the third main meta region 133a, the third corner meta region 133b, the fourth main meta region 134a, and the fourth corner meta region 134b may be different from each other in the nano-photonic lens array 130 shown in FIG. 4 and the nano-photonic lens array 130a shown in FIG. 7.

Even in the case of the nano-photonic lens array 130a shown in FIG. 7, distributions of the cross-sectional areas of the nanostructures NP in the first main meta region 131a, the first corner meta region 131b, the fourth main meta region 134a, and the fourth corner meta region 134b may be symmetrical with respect to lines extending in the first diagonal direction DG1 and the second diagonal direction DG2 which pass through the centers of the first main meta region 131a, the first corner meta region 131b, the fourth main meta region 134a, and the fourth corner meta region 134b. In addition, distributions of the cross-sectional areas of the nanostructures NP in the first main meta region 131a and the fourth main meta region 134a may be asymmetrical with respect to lines extending in the first direction and second direction which pass through the centers of the first main meta region 131a and the fourth main meta region 134a. Distributions of the cross-sectional areas of the nanostructures NP in the first main meta region 131a and the fourth main meta region 134a may be the same, and distributions of the cross-sectional areas of the nanostructures NP in the first corner meta region 131b and the fourth corner meta region 134b may be the same.

Distributions of the cross-sectional areas of the nanostructures NP in the second main meta region 132a, the second corner meta region 132b, the third main meta region 133a, and the third corner meta region 133b may be symmetrical with respect to lines extending in the first direction, the second direction, the first diagonal direction DG1, and the second diagonal direction DG2, which pass through the centers of the second main meta region 132a, the second corner meta region 132b, the third main meta region 133a, and the third corner meta region 133b.

Unlike the nano-photonic lens array 130 shown in FIG. 4, distributions of the cross-sectional areas of the nanostructures NP in the second main meta region 132a and the third main meta region 133a of the nano-photonic lens array 130a shown in FIG. 7 may be the same. In addition, distributions of the cross-sectional areas of the nanostructures NP in the second corner meta region 132b and the third corner meta region 133b of the nano-photonic lens array 130a shown in FIG. 7 may be the same.

For example, the nanostructures NP may be disposed at the centers of the first main meta region 131a, the second main meta region 132a, the third main meta region 133a, and the fourth main meta region 134a. The cross-sectional areas of the nanostructures NP disposed at the centers of the first main meta region 131a and the fourth main meta region 134a may be the same. In addition, the cross-sectional areas of the nanostructures NP disposed at the centers of the second main meta region 132a and the third main meta region 133a may be the same. On the other hand, the cross-sectional areas of the nanostructures NP disposed at the centers of the first main meta region 131a and the fourth main meta region 134a may be different from the cross-sectional areas of the nanostructures NP disposed at the centers of the second main meta region 132a and the third main meta region 133a.

In this case, the first main meta region 131a and the fourth main meta region 134a may be configured to transmit mixed light (e.g., magenta light) of a second wavelength band (e.g., red light) and a third wavelength band (e.g., blue light) in incident light to the second corner light sensing device 112b and the third corner light sensing device 113b in the first diagonal direction DG1. The first corner meta region 131b and the fourth corner meta region 134b may be configured to transmit the mixed light (e.g., magenta light) of the second wavelength band (e.g., red light) and the third wavelength band (e.g., blue light) in the incident light to the second main light sensing device 112a and the third main light sensing device 113a in the first diagonal direction DG1. In addition, the second main meta region 132a and the third main meta region 133a may be configured to transmit the light of the first wavelength band (e.g., green light) to the first corner light sensing device 111b and the fourth corner light sensing device 114b in the first diagonal direction DG1, and the second corner meta region 132b and the third corner meta region 133b may be configured to transmit the light of the first wavelength band to the first main light sensing device 111a and the fourth main light sensing device 114a in the first diagonal direction DG1.

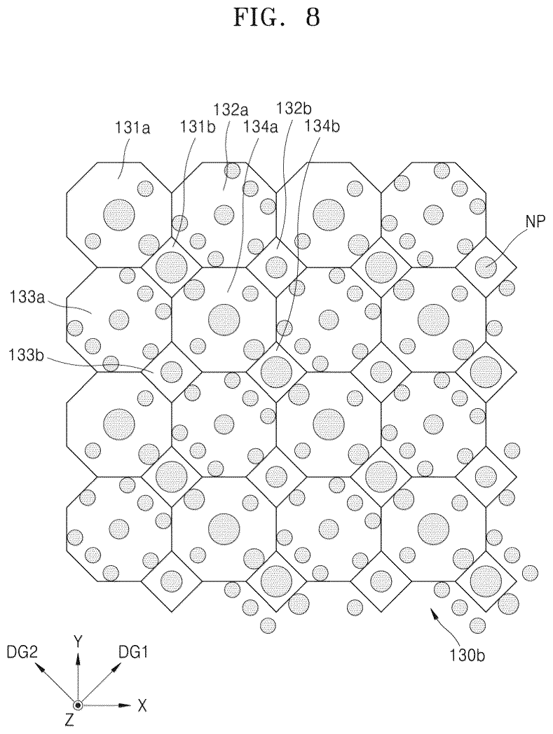

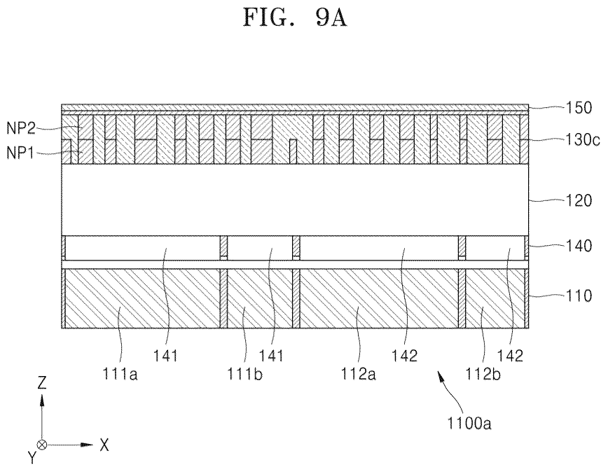

FIG. 8 is a plan view showing an example of an arrangement of the plurality of nanostructures NP of a nano-photonic lens array 130b according to another embodiment. In the case of the nano-photonic lens arrays 130 and 130a shown in FIGS. 4 and 7, the plurality of nanostructures NP are two-dimensionally arranged at regular intervals in the first diagonal direction DG1 and the second diagonal direction DG2. In other words, in the entire region of the nano-photonic lens arrays 130 and 130a, the plurality of nanostructures NP are two-dimensionally arranged in the form of a square grid inclined in the direction of 45 degrees. By contrast, in the nano-photonic lens array 130b shown in FIG. 8, arrangement intervals of the nanostructures NP may not be constant in the first diagonal direction DG1 and the second diagonal direction DG2.

Referring to FIG. 8, the nanostructures NP may be disposed at the centers of the first main meta region 131a, the first corner meta region 131b, the fourth main meta region 134a, and the fourth corner meta region 134b, and may be disposed at boundaries between the first main meta region 131a, the first corner meta region 131b, the fourth main meta region 134a, and the fourth corner meta region 134b in the second diagonal direction DG2. The nanostructures NP may be disposed at two edges of each of the first main meta region 131a and the fourth main meta region 134a in the first diagonal direction DG1. In addition, the nanostructures NP may be disposed at the centers of the second main meta region 132a, the second corner meta region 132b, the third main meta region 133a, and the third corner meta region 133b, and may be disposed at boundaries between the second main meta region 132a, the second corner meta region 132b, the third main meta region 133a, and the third corner meta region 133b in the second diagonal direction DG2. In addition, the plurality of nanostructures NP may be disposed at regular intervals in the second diagonal direction DG2 at two edges of each of the second main meta region 132a and the third main meta region 133a in the first diagonal direction DG1.

Rules of the distributions of the cross-sectional areas of the nanostructures NP in the first main meta region 131a, the first corner meta region 131b, the fourth main meta region 134a, and the fourth corner meta region 134b described with reference to FIG. 7 may also be applied to the nano-photonic lens array 130b shown in FIG. 8. For example, distributions of the cross-sectional areas of the nanostructures NP in the first main meta region 131a, the first corner meta region 131b, the fourth main meta region 134a, and the fourth corner meta region 134b may be symmetrical with respect to lines extending in the first diagonal direction DG1 and the second diagonal direction DG2 which pass through the centers of the first main meta region 131a, the first corner meta region 131b, the fourth main meta region 134a, and the fourth corner meta region 134b. In addition, distributions of the cross-sectional areas of the nanostructures NP in the first main meta region 131a and the fourth main meta region 134a may be asymmetrical with respect to lines extending in the first direction and the second direction which pass through the centers of the first main meta region 131a and the fourth main meta region 134a. Distributions of the cross-sectional areas of the nanostructures NP in the first main meta region 131a and the fourth main meta region 134a may be the same, and distributions of the cross-sectional areas of the nanostructures NP in the first corner meta region 131b and the fourth corner meta region 134b may be the same.

In the nano-photonic lens array 130b shown in FIG. 8, distributions of the cross-sectional areas of the nanostructures NP in the second main meta region 132a, the second corner meta region 132b, the third main meta region 133a, and the third corner meta region 133b may be symmetrical only with respect to lines extending in the first diagonal direction DG1 and the second diagonal direction DG2s which pass through the centers of the second main meta region 132a, the second corner meta region 132b, the third main meta region 133a, and the third corner meta region 133b. For example, distributions of the cross-sectional areas of the nanostructures NP in the second main meta region 132a and the third main meta region 133a may be asymmetrical with respect to lines extending in the first direction and the second direction which pass through the centers of the second main meta region 132a and the third main meta region 133a.

Like the nano-photonic lens array 130a of FIG. 7, the distributions of the cross-sectional areas of the nanostructures NP in the second main meta region 132a and the third main meta region 133a of the nano-photonic lens array 130b of FIG. 8 may be the same. In addition, the distributions of the cross-sectional areas of the nanostructures NP in the second corner meta region 132b and the third corner meta region 133b of the nano-photonic lens array 130b shown in FIG. 8 may be the same. Accordingly, mixed light (e.g., magenta light) of a second wavelength band and a third wavelength band may be provided to the second main light sensing device 112a and the third main light sensing device 113a in the first diagonal direction DG1.

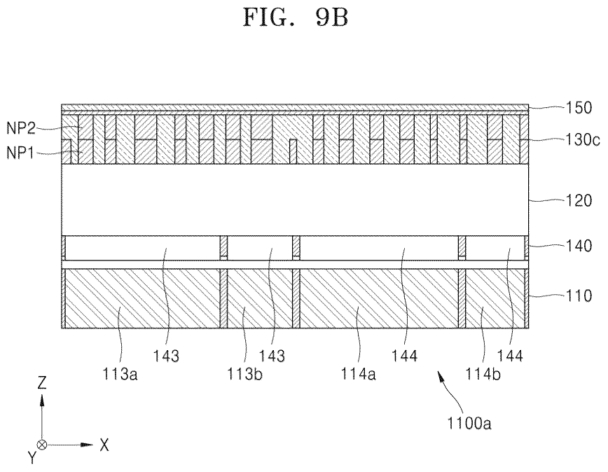

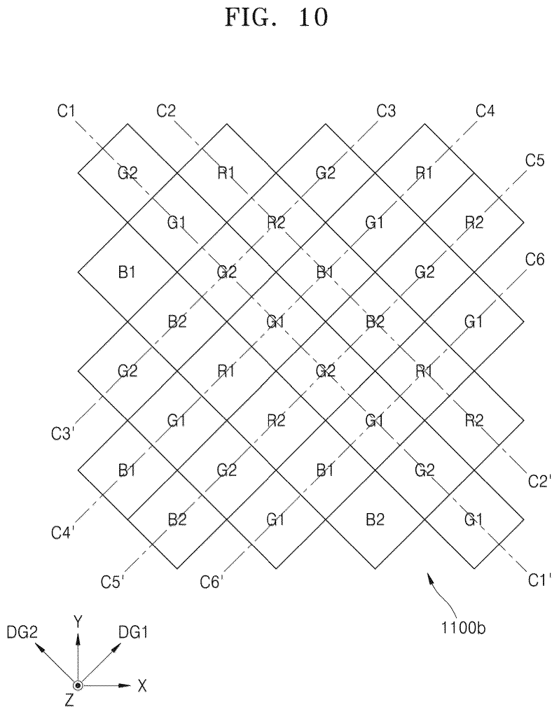

FIGS. 9A and 9B are cross-sectional views schematically showing a configuration of a pixel array 1100a of the image sensor 1000 according to another embodiment. Referring to FIGS. 9A and 9B, the pixel array 1100a according to another embodiment may include the sensor substrate 110, a color filter layer 140 disposed on the sensor substrate 110, the spacer layer 120 disposed on the color filter layer 140, a nano-photonic lens array 130c disposed on the spacer layer 120, and an anti-reflection layer 150 disposed on the nano-photonic lens array 130c. The configuration of the sensor substrate 110 is the same as that described with reference to FIGS. 3A to 3D, and thus, a detailed description thereof is omitted.

The color filter layer 140 may include a plurality of color filters that transmit light of a specific wavelength band and absorb light of another wavelength band. For example, the color filter layer 140 may include a first color filter 141 and a fourth color filter 144 that transmits light of a first wavelength band and absorbs light of another wavelength band, a second color filter 142 that transmits light of a second wavelength band and absorbs light of another wavelength band, and a third color filter 143 that transmits light of a third wavelength band and absorbs light of another wavelength band. In an example, the first color filter 141 and the fourth color filter 144 each may be a green color filter that transmits green light, the second color filter 142 may be a red color filter that transmits red light, and the third color filter 143 may be a blue color filter that transmits blue light.

The first color filter 141 may be disposed on the first main light sensing device 111a and the first corner light sensing device 111b, the second color filter 142 may be disposed on the second main light sensing device 112a and the second corner light sensing device 112b, the third color filter 143 may be disposed on the third main light sensing device 113a and the third corner light sensing device 113b, and the fourth color filter 144 may be disposed on the fourth main light sensing device 114a and the fourth corner light sensing device 114b. Incident light is color-separated to a significant degree by the nano-photonic lens array 130c, and thus, absorption loss by the color filter layer 140 may be low even when the color filter layer 140 is used. In addition, color purity may be improved by using the nano-photonic lens array 130c and the color filter layer 140 together. In particular, like the nano-photonic lens arrays 130a and 130b shown in FIGS. 7 and 8, when magenta light is focused onto the second main light sensing device 112a, the second corner light sensing device 112b, the third main light sensing device 113a, and the third corner light sensing device 113b, the second color filter 142 and the third color filter 143 may respectively separate the magenta light into red light and blue light.

The nano-photonic lens array 130c may include a nanostructure having a two-layer structure. For example, the nano-photonic lens array 130c may include a first nanostructure NP1 and a second nanostructure NP2 disposed on the first nanostructure NP1. A cross-sectional area of the second nanostructure NP may be the same as or less than a cross-sectional area of the first nanostructure NP1 disposed therebelow. Among entire nanostructures of the nano-photonic lens array 130c, some nanostructures may have a two-layer structure, and other nanostructures may include only the first nanostructure NP1. The nanostructures are formed in a two-layer structure, and thus, an aspect ratio of the nanostructures may be increased, and a degree of freedom of design with respect to the nano-photonic lens array 130c may be increased.

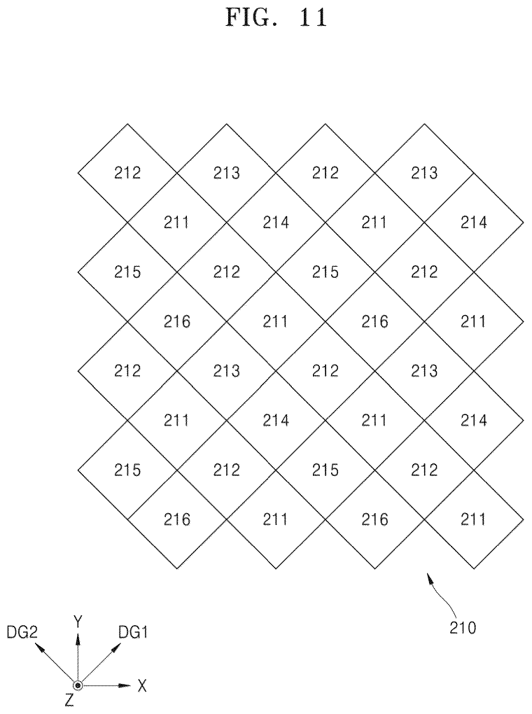

It has been described that pixels of the same color directly adjacent to each other in a diagonal direction in the pixel arrays 1100 and 1100a have different sizes, but it is also possible to implement an HDR function by designing all pixels to have the same size and different focusing efficiencies. FIG. 10 is a diagram showing an example of a pixel arrangement in a pixel array 1100b of an image sensor according to another embodiment. Referring to FIG. 10, the pixel array 1100b may include first green pixels G1 and second green pixels G2 adjacent to each other in the second diagonal direction DG2, first red pixels R1 and second red pixels R2 adjacent to each other in the second diagonal direction DG2, and first blue pixels B1 and second blue pixels B2 adjacent to each other in the second diagonal direction DG2. For example, a plurality of first green pixels G1 and a plurality of second green pixels G2 may be alternately arranged on a cross-section along a C1-C1′ line in the second diagonal direction DG2. The first red pixels R1, the second red pixels R2, the first blue pixels B1, and the second blue pixels B2 may be repeatedly arranged one by one on a cross-section along a C2-C2′ line in the second diagonal direction DG2.

The second green pixels G2, the second red pixels R2, the second green pixel G2, and the second blue pixels B2 may be repeatedly arranged one by one on a cross-section along a C3-C3′ line in the first diagonal direction DG1. In addition, the first green pixels G1, the first blue pixels B1, the first green pixels G1, and the first red pixels R1 may be repeatedly arranged one by one on a cross-section along a C4-C4′ line in the first diagonal direction DG1, the second green pixels G2, the second green pixels B2, the second green pixels G2, and the second red pixels R2 may be repeatedly arranged one by one on a cross-section along a C5-C5′ line in the first diagonal direction DG1, and the first green pixels G1, the first red pixels R1, the first green pixels G1, and the first blue pixels B1 may be repeatedly arranged one by one on a cross-section along a C6-C6′ line in the first diagonal direction DG1.

The first green pixel G1, the second green pixel G2, the first red pixel R1, the second red pixel R2, the first blue pixel B1, and the second blue pixel B2 may have a rectangular shape having the same size. In particular, each of the first green pixel G1, the second green pixel G2, the first red pixel R1, the second red pixel R2, the first blue pixel B1, and the second blue pixel B2 may have a rectangular shape inclined in the first diagonal direction DG1 or the second diagonal DG2. For example, four sides of each of the first green pixel G1, the second green pixel G2, the first red pixel R1, the second red pixel R2, the first blue pixel B1, and the second blue pixel B2 may be inclined in the first diagonal direction DG1 or the second diagonal DG2. In this case, pixels adjacent to each other may be disposed to share one side with each other.

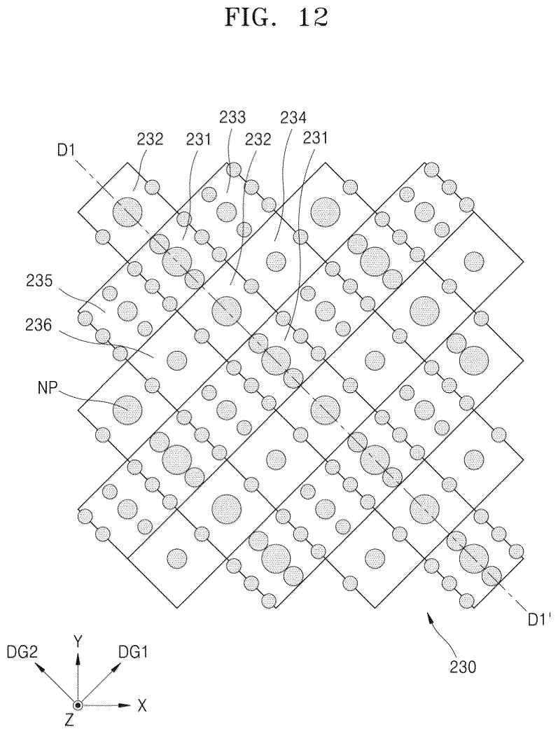

FIG. 11 is a schematic plan view of a sensor substrate 210 of the pixel array 1100b shown in FIG. 10. Referring to FIG. 11, the sensor substrate 210 may include a plurality of first light sensing devices 211 respectively corresponding to the plurality of first green pixels G1, a plurality of second light sensing devices 212 respectively corresponding to the plurality of second green pixels G2, a plurality of third light sensing devices 213 respectively corresponding to the plurality of first red pixels R1, a plurality of fourth light sensing devices 214 respectively corresponding to the plurality of second red pixels R2, a plurality of fifth light sensing devices 215 respectively corresponding to the plurality of first blue pixels B1, and a plurality of sixth light sensing devices 216 respectively corresponding to the plurality of second blue pixels B2.

The arrangement of the plurality of first light sensing devices 211, the plurality of second light sensing devices 212, the plurality of third light sensing devices 213, the plurality of fourth light sensing devices 214, the plurality of fifth light sensing devices 215, and the plurality of sixth light sensing devices 216 may be the same as the arrangement of the first green pixels G1, the second green pixels G2, the first red pixels R1, the second red pixels R2, the first blue pixels B1, and the second blue pixels B2 described above. For example, the plurality of first light sensing devices 211 and the plurality of second light sensing devices 212 may be alternately arranged on one cross-section in the second diagonal direction DG2. On another cross-section in the second diagonal direction DG2, the third light sensing devices 213, the fourth light sensing devices 214, the fifth light sensing devices 215, and the sixth light sensing devices 216 may be repeatedly arranged one by one. In addition, the plurality of first light sensing devices 211, the plurality of second light sensing devices 212, the plurality of third light sensing devices 213, the plurality of fourth light sensing devices 214, the plurality of fifth light sensing devices 215, and the plurality of sixth light sensing devices 216 may all have the same size, and may be two-dimensionally arranged in the first diagonal direction DG1 and the second diagonal direction DG2. In addition, the arrangement form of the first green pixels G1, the second green pixels G2, the first red pixels R1, the second red pixels R2, the first blue pixels B1, and the second blue pixels B2 described above may be applied to the plurality of first light sensing devices 211, the plurality of second light sensing devices 212, the plurality of third light sensing devices 213, the plurality of fourth light sensing devices 214, the plurality of fifth light sensing devices 215, and the plurality of sixth light sensing devices 216.

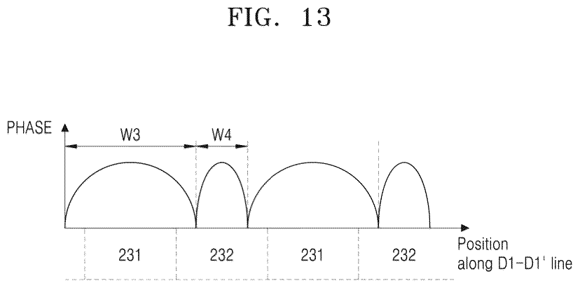

FIG. 12 is a plan view showing an example of an arrangement of the plurality of nanostructures NP of a nano-photonic lens array 230 to which the pixel array 1100b shown in FIG. 10 may be applied. Referring to FIG. 12, a nano-photonic lens array 230 may include a plurality of first meta regions 231 respectively corresponding to the plurality of first green pixels G1 or the plurality of first light sensing devices 211, a plurality of second meta regions 232 respectively corresponding to the plurality of second green pixels G2 or the plurality of second light sensing devices 212, a plurality of third meta regions 233 respectively corresponding to the plurality of first red pixels R1 or the plurality of third light sensing devices 213, a plurality of fourth meta regions 234 respectively corresponding to the plurality of second red pixels R2 or the plurality of fourth light sensing devices 214, a plurality of fifth meta regions 235 respectively corresponding to the plurality of first blue pixels B1 or the plurality of fifth light sensing devices 215, and a plurality of sixth meta regions 236 respectively corresponding to the plurality of second blue pixels B2 or the plurality of sixth light sensing devices 216. The arrangement of the plurality of first meta regions 231, the plurality of second meta regions 232, the plurality of third meta regions 233, the plurality of fourth meta regions 234, the plurality of fifth meta regions 235, and the plurality of sixth meta regions 236 may be the same as the arrangement of the first green pixels G1, the second green pixels G2, the first red pixels R1, the second red pixels R2, the first blue pixels B1, and the second blue pixels B2 described above. Accordingly, the description of the arrangement form and size of the first green pixels G1, the second green pixels G2, the first red pixels R1, the second red pixels R2, the first blue pixels B1, and the second blue pixels B2 may be applied to the plurality of first meta regions 231, the plurality of second meta regions 232, the plurality of third meta regions 233, the plurality of fourth meta regions 234, the plurality of fifth meta regions 235, and the plurality of sixth meta regions 236.

Each of the plurality of first meta regions 231, the plurality of second meta regions 232, the plurality of third meta regions 233, the plurality of fourth meta regions 234, the plurality of fifth meta regions 235, and the plurality of sixth meta regions 236 may include the plurality of nanostructures NP. According to an embodiment, the number of nanostructures NP disposed in the first meta regions 231 may be greater than the number of nanostructures NP disposed in the second meta regions 232. Likewise, the number of nanostructures NP disposed in the third meta region 233 may be greater than the number of nanostructures NP disposed in the fourth meta regions 234, and the number of nanostructures NP disposed in the fifth meta regions 235 may be greater than the number of nanostructures NP disposed in the sixth meta regions 236.

The arrangement rule of the nanostructures NP in the nano-photonic lens array 230 shown in FIG. 12 may be similar to the arrangement rule of the nanostructures NP in the nano-photonic lens array 130, 130a, or 130b shown in FIG. 4, 7, or 8. For example, distributions of the cross-sectional areas of the nanostructures NP in the first meta regions 231 and the second meta regions 232 may be symmetrical with respect to the first diagonal direction DG1 and the second diagonal direction DG2 which pass through the centers of the first meta regions 231 and the second meta regions 232. In addition, distributions of the cross-sectional areas of the nanostructures NP in the first meta regions 231 and the second meta regions 232 may be asymmetrical with respect to the first direction and the second direction which pass through the centers of the first meta regions 231 and the second meta regions 232.

Distributions of the cross-sectional areas of the nanostructures NP in the third meta regions 233, the fourth meta regions 234, the fifth meta regions 235, and the sixth meta regions 236 may be symmetrical with respect to lines extending in the first diagonal direction DG1 and the second diagonal direction DG2 which pass through the centers of the third meta regions 233, the fourth meta regions 234, the fifth meta regions 235, and the sixth meta regions 236. In addition, the distributions of the cross-sectional areas of the nanostructures NP in the third meta regions 233, the fourth meta regions 234, the fifth meta regions 235, and the sixth meta regions 236 may be asymmetrical with respect to lines extending in the first direction and the second direction which pass through the centers of the third meta regions 233, the fourth meta regions 234, the fifth meta regions 235, and the sixth meta regions 236.

For example, the nanostructures NP may be disposed at the centers of the first meta regions 231, the second meta regions 232, the third meta regions 233, the fourth meta regions 234, the fifth meta regions 235, and the sixth meta regions 236. The cross-sectional areas of the nanostructures NP disposed at the centers of the first meta regions 231 and the second meta regions 232 may be the same. The cross-sectional areas of the nanostructures NP disposed at the centers of the third meta regions 233, the fourth meta regions 234, the fifth meta regions 235, and the sixth meta regions 236 may be identical to each other and different from the cross-sectional areas of the nanostructures NP disposed at the centers of the first meta regions 231 and the second meta regions 232. In addition, at least two nanostructures NP disposed to face each other in the first diagonal direction DG1 or in the second diagonal direction DG2 with respect to the central nanostructure NP may be further provided in the first meta regions 231, the second meta regions 232, the third meta regions 233, the fourth meta regions 234, the fifth meta regions 235, and the sixth meta regions 236. The two nanostructures NP disposed to face each other in the first diagonal direction DG1 or in the second diagonal direction DG2 in the first meta regions 231, the second meta regions 232, the third meta regions 233, the fourth meta regions 234, the fifth meta regions 235, and the sixth meta regions 236 may have the same cross-sectional area. In addition, the nanostructures NP disposed to face each other in the first diagonal direction DG1 and the nanostructures NP disposed to face each other in the second diagonal direction DG2 in the first meta regions 231, the second meta regions 232, the third meta regions 233, the fourth meta regions 234, the fifth meta regions 235, and the sixth meta regions 236 may have different cross-sectional areas.

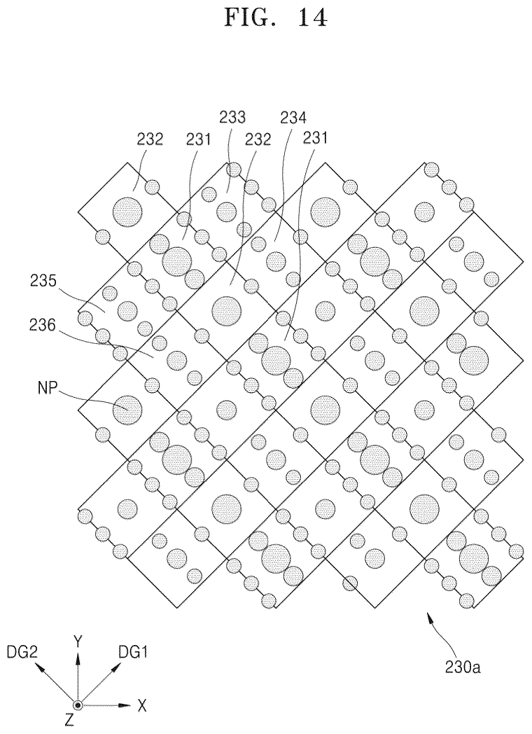

FIG. 13 is a diagram showing an example of a phase profile of green light passing through the nano-photonic lens array 230 shown in FIG. 12. In particular, FIG. 13 shows the phase profile of green light on a cross-section of the nano-photonic lens array 230 along a D1-D1′ line in the second diagonal direction DG2. Referring to FIG. 13, the green light on a lower surface of the nano-photonic lens array 230 may have the phase profile that is the largest at the center of each of the first meta region 231 and the second meta region 232 and is reduced in the direction away from each center. In particular, the phase profile of green light may be the smallest inside between the center and the edge of the second meta region 232. As a result, a third width W3 of the phase profile of green light formed at a position corresponding to the first meta region 231 in the second diagonal direction DG2 may be greater than a fourth width W4 of the phase profile of green light formed at a position corresponding to the second meta region 232 in the second diagonal direction DG2.

Accordingly, a focusing region corresponding to the first green pixel G1 formed by the nano-photonic lens array 230 may be wider than a focusing region corresponding to the second green pixel G2. Likewise, a focusing region corresponding to the first red pixel R1 may be wider than a focusing region corresponding to the second red pixel R2, and a focusing region corresponding to the first blue pixel B1 may be wider than a focusing region corresponding to the second blue pixel B2. In other words, the intensity of light in a first wavelength band focused onto the first light sensing device 211 may be greater than the intensity of light in the first wavelength band focused onto the second light sensing device 212, the intensity of light in a second wavelength band focused onto the third light sensing device 213 may be greater than the intensity of light in the second wavelength band focused onto the fourth light sensing device 214, and the intensity of light in a third wavelength band focused onto the fifth light sensing device 215 may be greater than the intensity of light in the third wavelength band focused onto the sixth light sensing device 216. As a result, the sensitivity of the first green pixel G1 may be greater than the sensitivity of the second green pixel G2, the sensitivity of the first red pixel R1 may be greater than the sensitivity of the second red pixel R2, and the sensitivity of the first blue pixel B1 may be greater than the sensitivity of the second blue pixel B2. In this case, the second green pixel G2 may perform the same function as a green corner pixel, the second red pixel R2 may perform the same function as a red corner pixel, and the second blue pixel B2 may perform the same function as a blue corner pixel.

FIG. 14 is a plan view showing an example of an arrangement of the plurality of nanostructures NP of a nano-photonic lens array 230a according to another embodiment. The nano-photonic lens array 230a shown in FIG. 14 includes the plurality of nanostructures NP arranged based on the same rule as the nano-photonic lens array 230 shown in FIG. 12, and differs only in positions and cross-sectional areas of some of the nanostructures NP. As described above, the arrangement of nanostructures NP for implementing the above-described color separation and focusing functions of the nano-photonic lens array 230 described with reference to FIGS. 12 and 13 is not limited to the example shown in FIG. 12, and various other arrangements of nanostructures NP may be possible.

The image sensor 1000 according to an embodiment may have improved light utilization efficiency and minimize resolution degradation because the nano-photonic lens array color-separates incident light and focuses the color-separated light on each pixel without absorbing or reflecting the incident light.

Accordingly, it is possible to reduce the size of one pixel of the image sensor 1000 or sizes of independent light sensing cells in the pixel, and thus, the image sensor 1000 having a higher resolution may be provided. In addition, according to an embodiment, two pixels of the same color arranged adjacent to each other in a diagonal direction may have different sensitivities, and thus, a contrast ratio of an image may be greatly improved by using pixels with relatively high sensitivity and pixels with relatively low sensitivity. The image sensor 1000 according to the embodiment may form a camera module along with a module lens of various functions and may be utilized in various electronic apparatuses.

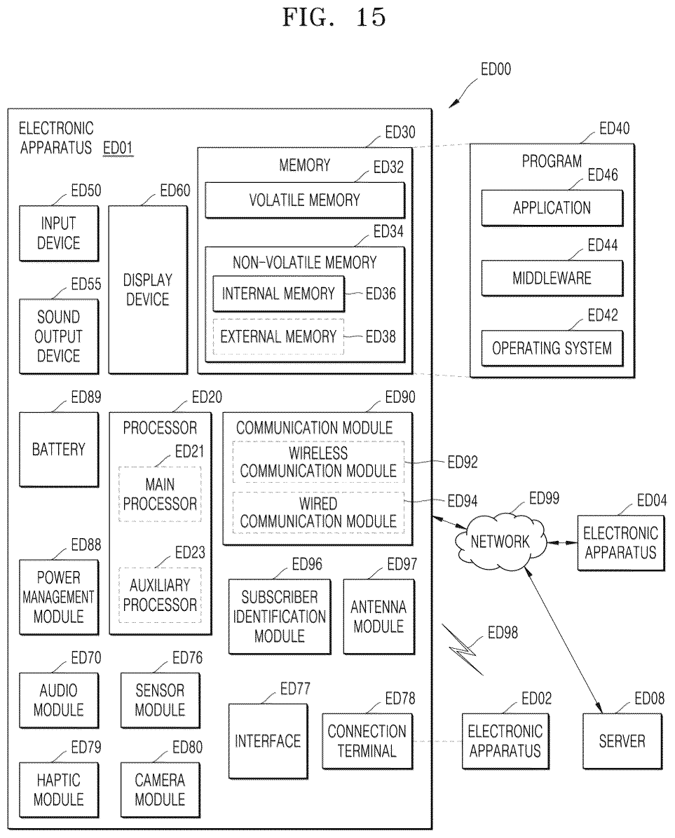

FIG. 15 is a block diagram showing an example of an electronic apparatus ED01 including the image sensor 1000. Referring to FIG. 15, in a network environment ED00, the electronic apparatus ED01 may communicate with another electronic apparatus ED02 via a first network ED98 (short-range wireless communication network, etc.), or may communicate with another electronic apparatus ED04 and/or a server ED08 via a second network ED99 (long-range wireless communication network, etc.) The electronic apparatus ED01 may communicate with the electronic apparatus ED04 via the server ED08. The electronic apparatus ED01 may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some (display device ED60, etc.) of the elements may be omitted or another element may be added. Some of the elements may be configured as one integrated circuit. For example, the sensor module ED76 (a fingerprint sensor, an iris sensor, an illuminance sensor, etc.) may be embedded and implemented in the display device ED60 (display, etc.)

The processor ED20 may control one or more elements (hardware, software elements, etc.) of the electronic apparatus ED01 connected to the processor ED20 by executing software (program ED40, etc.), and may perform various data processes or operations. As a part of the data processes or operations, the processor ED20 may load a command and/or data received from another element (sensor module ED76, communication module ED90, etc.) to a volatile memory ED32, may process the command and/or data stored in the volatile memory ED32, and may store result data in a non-volatile memory ED34. The processor ED20 may include a main processor ED21 (central processing unit, application processor, etc.) and an auxiliary processor ED23 (graphic processing unit, image signal processor, sensor hub processor, communication processor, etc.) that may be operated independently from or along with the main processor ED21. The auxiliary processor ED23 may use less power than that of the main processor ED21, and may perform specified functions.

The auxiliary processor ED23, on behalf of the main processor ED21 while the main processor ED21 is in an inactive state (sleep state) or along with the main processor ED21 while the main processor ED21 is in an active state (application executed state), may control functions and/or states related to some (display device ED60, sensor module ED76, communication module ED90, etc.) of the elements in the electronic apparatus ED01. The auxiliary processor ED23 (image signal processor, communication processor, etc.) may be implemented as a part of another element (camera module ED80, communication module ED90, etc.) that is functionally related thereto.

The memory ED30 may store various data required by the elements (processor ED20, sensor module ED76, etc.) of the electronic apparatus ED01. The data may include, for example, input data and/or output data about software (program ED40, etc.) and commands related thereto. The memory ED30 may include the volatile memory ED32 and/or the non-volatile memory ED34.

The program ED40 may be stored as software in the memory ED30, and may include an operation system ED42, middleware ED44, and/or an application ED46.

The input device ED50 may receive commands and/or data to be used in the elements (processor ED20, etc.) of the electronic apparatus ED01, from outside (user, etc.) of the electronic apparatus ED01. The input device ED50 may include a microphone, a mouse, a keyboard, and/or a digital pen (stylus pen).

The sound output device ED55 may output a sound signal to outside of the electronic apparatus ED01. The sound output device ED55 may include a speaker and/or a receiver. The speaker may be used for a general purpose such as multimedia reproduction or record play, and the receiver may be used to receive a call. The receiver may be coupled as a part of the speaker or may be implemented as an independent device.

The display device ED60 may provide visual information to outside of the electronic apparatus ED01. The display device ED60 may include a display, a hologram device, or a projector, and a control circuit for controlling the corresponding device. The display device ED60 may include a touch circuitry set to sense a touch, and/or a sensor circuit (pressure sensor, etc.) that is set to measure a strength of a force generated by the touch.

The audio module ED70 may convert sound into an electrical signal or vice versa. The audio module ED 70 may acquire sound through the input device ED50, or may output sound via the sound output device ED55 and/or a speaker and/or a headphone of another electronic apparatus (electronic apparatus ED02, etc.) connected directly or wirelessly to the electronic apparatus ED01.

The sensor module ED76 may sense an operating state (power, temperature, etc.) of the electronic apparatus ED01, or an outer environmental state (user state, etc.), and may generate an electrical signal and/or data value corresponding to the sensed state. The sensor module ED76 may include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The interface ED77 may support one or more designated protocols that may be used in order for the electronic apparatus ED01 to be directly or wirelessly connected to another electronic apparatus (electronic apparatus ED02, etc.) The interface ED77 may include a high-definition multimedia interface (HDMI), a universal serial bus (USB) interface, an SD card interface, and/or an audio interface.

The connection terminal ED78 may include a connector by which the electronic apparatus ED01 may be physically connected to another electronic apparatus (electronic apparatus ED02, etc.). The connection terminal ED78 may include an HDMI connector, a USB connector, an SD card connector, and/or an audio connector (headphone connector, etc.).

The haptic module ED79 may convert the electrical signal into a mechanical stimulation (vibration, motion, etc.) or an electric stimulation that the user may sense through a tactile or motion sensation. The haptic module ED79 may include a motor, a piezoelectric device, and/or an electric stimulus device.

The camera module ED80 may capture a still image and a video. The camera module ED80 may include a lens assembly including one or more lenses, the image sensor 1000 of FIG. 1, image signal processors, and/or flashes. The lens assembly included in the camera module ED80 may collect light emitted from an object that is an object to be captured.

The power management module ED88 may manage the power supplied to the electronic apparatus ED01. The power management module ED88 may be implemented as a part of a power management integrated circuit (PMIC).

The battery ED89 may supply electric power to components of the electronic apparatus ED01. The battery ED89 may include a primary battery that is not rechargeable, a secondary battery that is rechargeable, and/or a fuel cell.

The communication module ED90 may support the establishment of a direct (wired) communication channel and/or a wireless communication channel between the electronic apparatus ED01 and another electronic apparatus (electronic apparatus ED02, electronic apparatus ED04, server ED08, etc.), and execution of communication through the established communication channel. The communication module ED90 may be operated independently from the processor ED20 (application processor, etc.), and may include one or more communication processors that support the direct communication and/or the wireless communication. The communication module ED90 may include a wireless communication module ED92 (cellular communication module, a short-range wireless communication module, a global navigation satellite system (GNSS) communication module) and/or a wired communication module ED94 (local area network (LAN) communication module, a power line communication module, etc.). From among the communication modules, a corresponding communication module may communicate with another electronic apparatus via a first network ED09 (short-range communication network such as Bluetooth, WiFi direct, or infrared data association (IrDA)) or a second network ED99 (long-range communication network such as a cellular network, Internet, or computer network (LAN, WAN, etc.)). Such above various kinds of communication modules may be integrated as one element (single chip, etc.) or may be implemented as a plurality of elements (a plurality of chips) separately from one another. The wireless communication module ED92 may identify and authenticate the electronic apparatus ED01 in a communication network such as the first network ED98 and/or the second network ED99 by using subscriber information (international mobile subscriber identifier (IMSI), etc.) stored in the subscriber identification module ED96.

The antenna module ED97 may transmit or receive the signal and/or power to/from outside (another electronic apparatus, etc.). An antenna may include a radiator formed as a conductive pattern formed on a substrate (PCB, etc.). The antenna module ED97 may include one or more antennas. When the antenna module ED97 includes a plurality of antennas, from among the plurality of antennas, an antenna that is suitable for the communication type used in the communication network such as the first network ED98 and/or the second network ED99 may be selected by the communication module ED90. The signal and/or the power may be transmitted between the communication module ED90 and another electronic apparatus via the selected antenna. Another component (RFIC, etc.) other than the antenna may be included as a part of the antenna module ED97.

Some of the elements may be connected to one another via the communication method among the peripheral devices (bus, general purpose input and output (GPIO), serial peripheral interface (SPI), mobile industry processor interface (MIPI), etc.) and may exchange signals (commands, data, etc.)

The command or data may be transmitted or received between the electronic apparatus ED01 and the external electronic apparatus ED04 via the server ED08 connected to the second network ED99. Other electronic apparatuses ED02 and ED04 may be the devices that are the same as or different kinds from the electronic apparatus ED01. All or some of the operations executed in the electronic apparatus ED01 may be executed in one or more devices among the other electronic apparatuses ED02, ED04, and ED08. For example, when the electronic apparatus ED01 has to perform a certain function or service, the electronic apparatus ED01 may request one or more other electronic apparatuses to perform some or entire function or service, instead of executing the function or service by itself. One or more electronic apparatuses receiving the request execute an additional function or service related to the request and may transfer a result of the execution to the electronic apparatus ED01. To this end, for example, a cloud computing, a distributed computing, or a client-server computing technique may be used.

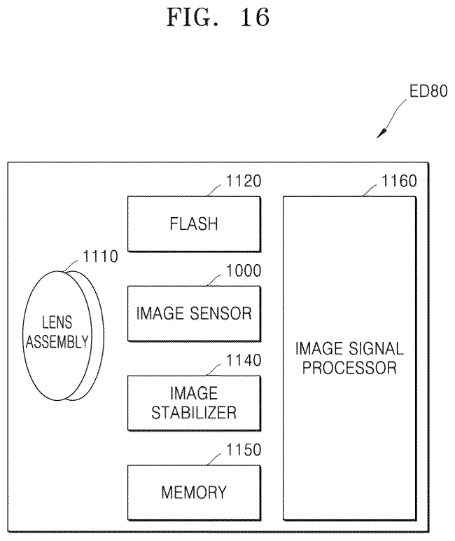

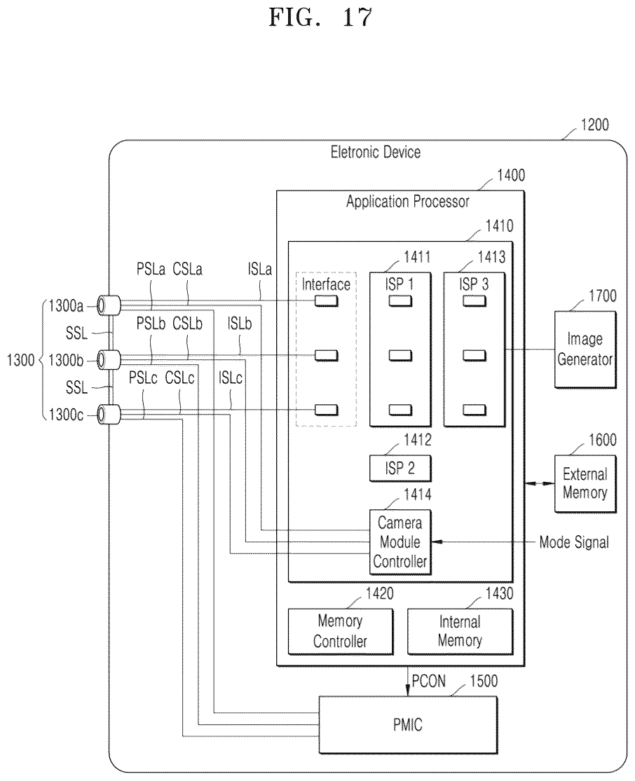

FIG. 16 is a block diagram showing an example of the camera module ED80 included in the electronic apparatus ED01 of FIG. 15. Referring to FIG. 24, the camera module ED80 may include a lens assembly 1110, a flash 1120, an image sensor 1000, an image stabilizer 1140, a memory 1150 (buffer memory, etc.), and/or an image signal processor 1160. The lens assembly 1110 may collect light emitted from an object that is to be captured. The camera module ED80 may include a plurality of lens assemblies 1110, and in this case, the camera module ED80 may include a dual camera module, a 360-degree camera, or a spherical camera. Some of the plurality of lens assemblies 1110 may have the same lens properties (viewing angle, focal distance, auto-focus, F number, optical zoom, etc.) or different lens properties. The lens assembly 1110 may include a wide-angle lens or a telephoto lens.

The flash 1120 may emit light that is used to strengthen the light emitted or reflected from the object. The flash 1120 may emit visible light or infrared-ray light. The flash 1120 may include one or more light-emitting diodes (red-green-blue (RGB)) LED, white LED, infrared LED, ultraviolet LED, etc.), and/or a Xenon lamp. The image sensor 1000 may be the image sensor described above with reference to FIG. 1, and converts the light emitted or reflected from the object and transferred through the lens assembly 1110 into an electrical signal to obtain an image corresponding to the object.

The image stabilizer 1140, in response to a motion of the camera module ED80 or the electronic apparatus 1101 including the camera module ED80, moves one or more lenses included in the lens assembly 1110 or the image sensor 1000 in a certain direction or controls the operating characteristics of the image sensor 1000 (adjusting of a read-out timing, etc.) in order to compensate for a negative influence of the motion. The image stabilizer 1140 may sense the movement of the camera module ED80 or the electronic apparatus ED01 by using a gyro sensor or an acceleration sensor disposed in or out of the camera module ED80. The image stabilizer 1140 may be implemented as an optical type.

The memory 1150 may store some or entire data of the image obtained through the image sensor 1000 for next image processing operation. For example, when a plurality of images are obtained at a high speed, obtained original data (Bayer-patterned data, high-resolution data, etc.) is stored in the memory 1150, and a low-resolution image is only displayed. Then, original data of a selected image (user selection, etc.) may be transferred to the image signal processor 1160. The memory 1150 may be integrated with the memory ED30 of the electronic apparatus ED01, or may include an additional memory that is operated independently.

The image signal processor 1160 may perform image treatment on the image obtained through the image sensor 1000 or the image data stored in the memory 1150. The image treatments may include a depth map generation, a three-dimensional modeling, a panorama generation, extraction of features, an image combination, and/or an image compensation (noise reduction, resolution adjustment, brightness adjustment, blurring, sharpening, softening, etc.). The image signal processor 1160 may perform controlling (exposure time control, read-out timing control, etc.) of the elements (image sensor 1000, etc.) included in the camera module ED80. Also, the image signal processor 1160 may generate a full-color image by executing the above demosaic algorithm. For example, when the demosaic algorithm is executed to generate the full-color image, the image signal processor 1160 may reconstruct most of the spatial resolution information by using an image signal of a green channel or yellow channel having high spatial sampling rate.

The image processed by the image signal processor 1160 may be stored again in the memory 1150 for additional process, or may be provided to an external element of the camera module ED80 (e.g., the memory ED30, the display device ED60, the electronic apparatus ED02, the electronic apparatus ED04, the server ED08, etc.). The image signal processor 1160 may be integrated with the processor ED20, or may be configured as an additional processor that is independently operated from the processor ED20. When the image signal processor 1160 is configured as an additional processor separately from the processor ED20, the image processed by the image signal processor 1160 undergoes through an additional image treatment by the processor ED20 and then may be displayed on the display device ED60.

Also, the image signal processor 1160 may receive two output signals independently from the adjacent photosensitive cells in each pixel or sub-pixel of the image sensor 1000, and may generate an auto-focusing signal from a difference between the two output signals. The image signal processor 1160 may control the lens assembly 1110 so that the focus of the lens assembly 1110 may be accurately formed on the surface of the image sensor 1000 based on the auto-focusing signal.

The electronic apparatus ED01 may further include one or a plurality of camera modules having different properties or functions. The camera module may include elements similar to those of the camera module ED80 of FIG. 16, and the image sensor included in the camera module may be implemented as a CCD sensor and/or a CMOS sensor and may include one or a plurality of sensors selected from the image sensors having different properties, such as an RGB sensor, a black and white (BW) sensor, an IR sensor, or a UV sensor. In this case, one of the plurality of camera modules ED80 may include a wide-angle camera and another camera module ED80 may include a telephoto camera. Similarly, one of the plurality of camera modules ED80 may include a front camera and another camera module ED80 may include a rear camera.

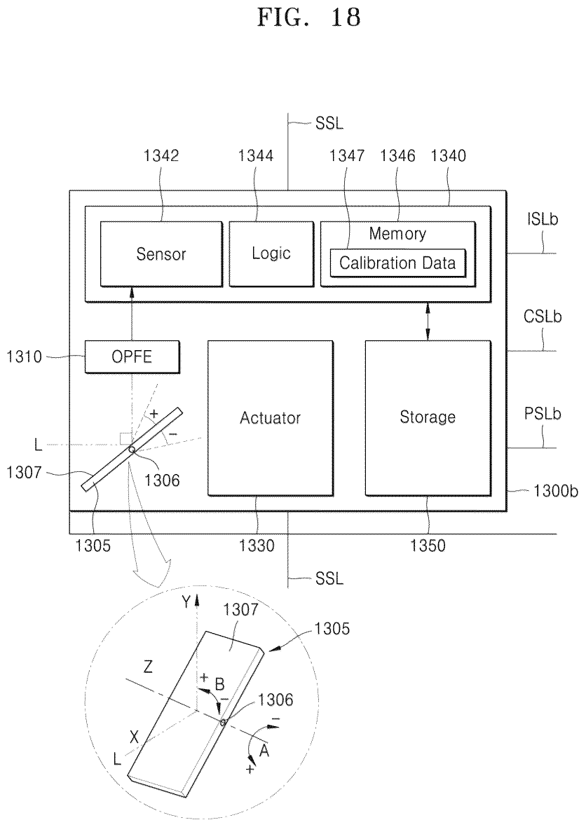

FIG. 17 is a block diagram of an electronic apparatus including a multi-camera module, and FIG. 18 is a detailed block diagram of the camera module in the electronic apparatus shown in FIG. 17.

Referring to FIG. 17, an electronic apparatus 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although the drawings show an example in which three camera modules 1300a, 1300b, and 1300c are arranged, one or more embodiments are not limited thereto. In one or more embodiments, the camera module group 1300 may be modified to include only two camera modules. Also, in one or more embodiments, the camera module group 1300 may be modified to include n (n is 4 or greater natural number) camera modules.

Hereinafter, detailed configuration of one camera module 1300b is described in detail below with reference to FIG. 18, but the description provided below may be also applied to the other camera modules 1300a and 1300c according to the embodiment.

Referring to FIG. 18, the camera module 1300b may include a prism 1305, an optical path folding element (OPFE) 1310, an actuator 1330, an image sensing device 1340, and a storage 1350.

The prism 1305 may include a reflecting surface 1307 having a light-reflecting material and may deform a path of light L incident from outside.

In one or more embodiments, the prism 1305 may change the path of the light L incident in the first direction (X-direction) into a second direction (Y-direction) that is perpendicular to the first direction (X-direction). Also, the prism 1305 may rotate the reflecting surface 1307 having the light-reflecting material about a center axis 1106 in a direction A, or about the center axis 1306 in a direction B so that the path of the light L incident in the first direction (X-direction) may be changed to the second direction (Y-direction) perpendicular to the first direction (X-direction). Here, the OPFE 1310 may also move in the third direction (Z-direction) that is perpendicular to the first direction (X-direction) and the second direction (Y-direction).

In one or more embodiments, as shown in the drawings, the maximum rotation angle of the prism 1305 in the direction A is 15° or less in the positive A direction and is greater than 15° in the negative A direction, but the embodiments are not limited thereto.

In one or more embodiments, the prism 1305 may be moved by the angle of about 20°, or between 10° to 20° or 15° to 20° in the positive or negative B direction. Here, the moving angle is the same in the positive or negative B direction, or may be similar within a range of about 1°.

In one or more embodiments, the prism 1305 may move the reflecting surface 1307 of the light-reflective material in the third direction (e.g., Z direction) that is parallel to the direction in which the center axis 1306 extends.

The OPFE 1310 may include, for example, optical lenses formed as m groups (here, m is a natural number). Here, m lenses move in the second direction (Y-direction) and may change an optical zoom ratio of the camera module 1300b. For example, when a basic optical zoom ratio of the camera module 1300b is Z and m optical lenses included in the OPFE 1310 move, the optical zoom ratio of the camera module 1300b may be changed to 3Z, 5Z, or 10Z or greater.

The actuator 1330 may move the OPFE 1310 or the optical lens (hereinafter, referred to as optical lens) to a certain position. For example, the actuator 1330 may adjust the position of the optical lens so that the image sensor 1342 may be located at a focal length of the optical lens for exact sensing operation.

An image sensing device 1340 may include the image sensor 1342, a control logic 1344, and a memory 1346. The image sensor 1342 may sense an image of a sensing target by using the light L provided through the optical lens. The control logic 1344 may control the overall operation of the camera module 1300b. For example, the control logic 1344 may control the operations of the camera module 1300b according to a control signal provided through a control signal line CSLb.

For example, the image sensor 1342 may include the nano-photonic lens array described above. The image sensor 1342 may receive more signals separated according to wavelengths in each pixel by using the nano-photonic lens array based on the nanostructures. Due to the above effects, the optical intensity required to generate high quality images at high resolution and low illuminance may be secured.

The memory 1346 may store information that is necessary for the operation of the camera module 1300b, e.g., calibration data 1347. The calibration data 1347 may include information that is necessary to generate image data by using the light L provided from outside through the camera module 1300b. The calibration data 1347 may include, for example, information about the degree of rotation described above, information about the focal length, information about an optical axis, etc. When the camera module 1300b is implemented in the form of a multi-state camera of which the focal length is changed according to the position of the optical lens, the calibration data 1347 may include information related to focal length values of the optical lens according to each position (or state) and auto-focusing.

The storage unit 1350 may store image data sensed through the image sensor 1342. The storage unit 1350 may be disposed out of the image sensing device 1340 and may be stacked with a sensor chip included in the image sensing device 1340. In one or more embodiments, the storage unit 1350 may be implemented as electrically erasable programmable read-only memory (EEPROM), but one or more embodiments are not limited thereto.

Referring to FIGS. 17 and 18 together, in one or more embodiments, each of the plurality of camera modules 1300a, 1300b, and 1300c may include the actuator 1330. Accordingly, each of the plurality of camera modules 1300a, 1300b, and 1300c may include the calibration data 1347 that is the same as or different from the others, according to the operation of the actuator 1330 included therein.

In one or more embodiments, one (for example, 1300b) of the plurality of camera modules 1300a, 1300b, and 1300c may be a camera module in a folded lens type including the prism 1305 and the OPFE 1310 described above, and the other camera modules (for example, 1300a and 1300c) may be vertical type camera modules not including the prism 1305 and the OPFE 1310. However, the disclosure is not limited thereto.

In one or more embodiments, one (for example, 1300c) of the plurality of camera modules 1300a, 1300b, and 1300c may be a depth camera of a vertical type, which extracts depth information by using infrared ray (IR).

In one or more embodiments, at least two camera modules (e.g., 1300a and 1300b) from among the plurality of camera module 1300a, 1300b, and 1300c may have different fields of view. In this case, for example, the optical lenses of the at least two camera modules (e.g., 1300a and 1300b) from among the plurality of camera modules 1300a, 1300b, and 1300c may be different from each other, but one or more embodiments are not limited thereto.

Also, in one or more embodiments, the plurality of camera modules 1300a, 1300b, and 1300c may have different fields of view from one another. In this case, the optical lenses respectively included in the plurality of camera modules 1300a, 1300b, and 1300c may be different from one another, but the disclosure is not limited thereto.

In one or more embodiments, the plurality of camera modules 1300a, 1300b, and 1300c may be physically isolated from one another. That is, the sensing region of one image sensor 1342 may not be divided and used by the plurality of camera modules 1300a, 1300b, and 1300c, but the plurality of camera modules 1300a, 1300b, and 1300c may each have an independent image sensor 1342 provided therein.

Referring back to FIG. 17, the application processor 1400 may include an image processing device 1410, a memory controller 1420, and an internal memory 1430. The application processor 1400 may be separately implemented from the plurality of camera modules 1300a, 1300b, and 1300c. For example, the application processor 1400 and the plurality of camera modules 1300a, 1300b, and 1300c may be separately implemented as separate semiconductor chips.

The image processing device 1410 may include a plurality of image processors 1411, 1412, and 1413, and a camera module controller 1414.

The image data generated by each of the camera modules 1300a, 1300b, and 1300c may be provided to the image processing device 1410 via separate image signal lines, respectively. The image data transfer may be carried out by using a camera serial interface (CSI) based on a mobile industry processor interface (MIPI), for example, but is not limited thereto.

The image data transferred to the image processing device 1410 may be stored in an external memory 1600 before being transferred to the image processors 1411 and 1412. The image data stored in the external memory 1600 may be provided to the image processor 1411 and/or the image processor 1412. The image processor 1411 may correct the image data in order to generate video. The image processor 1412 may correct the image data in order to generate still images. For example, the image processors 1411 and 1412 may perform a pre-processing operation such as a color calibration, a gamma calibration on the image data.

The image processor 1411 may include sub-processors. When the number of sub-processors is equal to the number of camera modules 1300a, 1300b, and 1300c, each of the sub-processors may process the image data provided from one camera module. When the number of sub-processors is less than the number of camera modules 1300a, 1300b, and 1300c, at least one of the sub-processors may process the image data provided from a plurality of camera module by using a timing-sharing process. The image data processed by the image processor 1411 and/or the image processor 1412 may be stored in the external memory 1600 before being transferred to the image processor 1413. The image data stored in the external memory 1600 may be transferred to the image processor 1412. The image processor 1412 may perform a post-processing operation such as a noise calibration, a sharpen calibration, etc. on the image data.

The image data processed in the image processor 1413 may be provided to the image generator 1700. The image generator 1700 may generate a final image by using the image data provided from the image processor 1413 according to image generating information or a mode signal.

In detail, the image generator 1700 may generate by merging at least parts of the image data generated by the camera modules 1300a, 1300b, and 1300c having different fields of view, according to image generating information or the mode signal. Also, the image generator 1700 may generate the output image by selecting one of pieces of image data generated by the camera modules 1300a, 1300b, and 1300c having different fields of view, according to image generating information or the mode signal.

In one or more embodiments, the image generating information may include a zoom signal or a zoom factor. Also, in one or more embodiments, the mode signal may be, for example, a signal based on a mode selected by a user.

When the image generating information is a zoom signal (zoom factor) and the camera modules 1300a, 1300b, and 1300c have different fields of view (angles of view) from one another, the image generator 1700 may perform different operations according to the kind of zoom signal. For example, when the zoom signal is a first signal, the image data output from the camera module 1300a is merged with the image data output from the camera module 1300c, and then, the output image may be generated by using the merged image signal and the image data output from the camera module 1300b and not used in the merge. When the zoom signal is a second signal that is different from the first signal, the image generator 1700 may not perform the image data merging, and then, may generate the output image by selecting one piece of the image data output respectively from the camera modules 1300a, 1300b, and 1300c. However, one or more embodiments are not limited thereto, and the method of processing the image data may be modified as necessary.

The camera module controller 1414 may provide each of the camera modules 1300a, 1300b, and 1300c with a control signal. The control signals generated by the camera module controller 1414 may be provided to corresponding camera modules 1300a, 1300b, and 1300c via control signal lines CSLa, CSLb, and CSLc separated from one another.

In one or more embodiments, the control signal provided to the plurality of camera modules 1300a, 1300b, and 1300c from the camera module controller 1414 may include mode information according to the mode signal. The plurality of camera modules 1300a, 1300b, and 1300c may operate in a first operation mode and a second operation mode in relation to the sensing speed, based on the mode information.

In the first operation mode, the plurality of camera modules 1300a, 1300b, and 1300c may generate the image signal at a first speed (for example, generating an image signal of a first frame rate), encodes the image signal at a second speed that is faster than the first speed (for example, encoding the image signal of a second frame rate that is greater than the first frame rate), and transfers the encoded image signal to the application processor 1400. Here, the second speed may be 30 times faster than the first speed or less.

The application processor 1400 may store the received image signal, that is, the encoded mage signal, in the memory 1430 provided therein or the storage 1600 outside the application processor 1400, and then, reads and decodes the encoded signal from the memory 1430 or the storage 1600, and may display the image data generated based on the decoded image signal. For example, the image processors 1411 and 1412 in the image processing device 1410 may perform decoding, and may perform image processing on the decoded image signals.

In the second operation mode, the plurality of camera modules 1300a, 1300b, and 1300c generates an image signal at a third speed that is slower than the first speed (for example, generating the image signal of a third frame rate that is lower than the first frame rate), and may transfer the image signal to the application processor 1400. The image signal provided to the application processor 1400 may be a signal that is not encoded. The application processor 1400 may perform the image processing of the received image signal or store the image signal in the memory 1430 or the storage 1600.

The PMIC 1500 may supply the power, for example, the power voltage, to each of the plurality of camera modules 1300a, 1300b, and 1300c. For example, the PMIC 1500 may supply the first power to the camera module 1300a via a power signal line PSLa, the second power to the camera module 1300b via a power signal line PSLb, and the third power to the camera module 1300c via a power signal line PSLc, under the control of the application processor 1400.

The PMIC 1500 may generate the power corresponding to each of the plurality of camera modules 1300a, 1300b, and 1300c and may adjust the power level, in response to a power control signal PCON from the application processor 1400. The power control signal PCON may include a power adjusting signal for each operation mode of the plurality of camera modules 1300a, 1300b, and 1300c. For example, the operation mode may include a low power mode, and the power control signal PCON may include information about the camera module operating in the low-power mode and set power level. The levels of the power provided to the plurality of camera modules 1300a, 1300b, and 1300c may be equal to or different from each other. Also, the power level may be dynamically changed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a sensor substrate comprising a plurality of light sensing devices; and
a nano-photonic lens array comprising a plurality of nanostructures arranged to separate, from incident light, light in a first wavelength band, light in a second wavelength band different from the first wavelength band, and light in a third wavelength band different from the first wavelength band and the second wavelength band, and to focus the separated light onto each of the plurality of light sensing devices,
wherein the plurality of nanostructures are configured to cause light of a same wavelength to be focused onto each of two light sensing devices adjacent in a diagonal direction among the plurality of light sensing devices, and
wherein, for each of the two light sensing devices adjacent in the diagonal direction, the light of the same wavelength respectively focused thereon has a different intensity.

2. The image sensor of claim 1,
wherein the plurality of light sensing devices comprises a first main light sensing device, a second main light sensing device, a third main light sensing device, and a fourth main light sensing device which are arranged in a 2×2 array in a first direction and a second direction perpendicular to the first direction, and
wherein the plurality of light sensing devices further comprises a first corner light sensing device in contact with the first main light sensing device in the diagonal direction, a second corner light sensing device in contact with the second main light sensing device in the diagonal direction, a third corner light sensing device in contact with the third main light sensing device in the diagonal direction, and a fourth corner light sensing device in contact with the fourth main light sensing device in the diagonal direction.

3. The image sensor of claim 2, wherein
the first main light sensing device is larger than the first corner light sensing device, the second main light sensing device is larger than the second corner light sensing device, the third main light sensing device is larger than the third corner light sensing device, and the fourth main light sensing device is larger than the fourth corner light sensing device.

4. The image sensor of claim 2, wherein
the nano-photonic lens array comprises a first main meta region corresponding to the first main light sensing device, a first corner meta region corresponding to the first corner light sensing device, a second main meta region corresponding to the second main light sensing device, a second corner meta region corresponding to the second corner light sensing device, a third main meta region corresponding to the third main light sensing device, a third corner meta region corresponding to the third corner light sensing device, a fourth main meta region corresponding to the fourth main light sensing device, and a fourth corner meta region corresponding to the fourth corner light sensing device.

5. The image sensor of claim 4, wherein
the first main meta region is larger than the first corner meta region, the second main meta region is larger than the second corner meta region, the third main meta region is larger than the third corner meta region, and the fourth main meta region is larger than the fourth corner meta region.

6. The image sensor of claim 4,
wherein the plurality of nanostructures comprises a first plurality of nanostructures, a second plurality of nanostructures, a third plurality of nanostructures, and a fourth plurality of nanostructures,
wherein the first main meta region, the second main meta region, the third main meta region, and the fourth main meta region respectively comprise the first plurality of nanostructures, the second plurality of nanostructures, the third plurality of nanostructures, and the fourth plurality of nanostructures,
wherein each nanostructure of each of the first, the second, the third, and the fourth plurality of nanostructures comprises a cross-sectional area and has a position,
wherein the cross-sectional areas of at least two nanostructures, within each of the first, the second, the third, and the fourth plurality of nanostructures, are different, and
wherein the first corner meta region, the second corner meta region, the third corner meta region, and the fourth corner meta region each comprise at least one nanostructure.

7. The image sensor of claim 6,
wherein the position and the cross-sectional area of each nanostructure of each of the first, the second, the third, and the fourth plurality of nanostructures are configured to:
cause the light in the first wavelength band to be focused onto each of the first main light sensing device, the first corner light sensing device, the fourth main light sensing device, and the fourth corner light sensing device,
cause the light in the second wavelength band to be focused onto each of the second main light sensing device and the second corner light sensing device, and
cause the light in the third wavelength band to be focused onto each of the third main light sensing device and the third corner light sensing device, and
wherein the position and the cross-sectional area of each nanostructure of each of the first, the second, the third, and the fourth plurality of nanostructures are configured to:
cause an intensity of the light in the first wavelength band focused onto the first main light sensing device to be greater than an intensity of the light in the first wavelength band focused onto the first corner light sensing device,
cause an intensity of the light in the second wavelength band focused onto the second main light sensing device to be greater than an intensity of the light in the second wavelength band focused onto the second corner light sensing device,
cause an intensity of the light in the third wavelength band focused onto the third main light sensing device to be greater than an intensity of the light in the third wavelength band focused onto the third corner light sensing device, and
cause an intensity of the light in the first wavelength band focused onto the fourth main light sensing device to be greater than an intensity of the light in the first wavelength band focused onto the fourth corner light sensing device.

8. The image sensor of claim 6,
wherein a distribution of the cross-sectional areas of the first plurality of nanostructures is symmetrical with respect to a diagonal line passing through a center of the first main meta region in a first diagonal direction and a diagonal line passing through the center of the first main meta region in a second diagonal direction,
wherein a distribution of the cross-sectional areas of the fourth plurality of nanostructures is symmetrical with respect to a diagonal line passing through a center of the fourth main meta region in the first diagonal direction and a diagonal line passing through the center of the fourth main meta region in the second diagonal direction, and
wherein the first diagonal direction intersects the second diagonal direction.

9. The image sensor of claim 8,
wherein the distribution of the cross-sectional areas of the first plurality of nanostructures is asymmetrical with respect to a line passing through the center of the first main meta region in the first direction and a line passing through the center of the first main meta region in the second direction, and
wherein the distribution of the cross-sectional areas of the fourth plurality of nanostructures in the fourth main meta region are asymmetrical with respect to a line passing through the center of the fourth main meta region in the first direction and a line passing through the center of the fourth main meta region in the second direction.

10. The image sensor of claim 9, wherein the distribution of the cross-sectional areas of the first plurality of nanostructures and the distribution of the cross-sectional areas of the fourth plurality of nanostructures are the same.

11. The image sensor of claim 9,
wherein a distribution of the cross-sectional areas of the second plurality of nanostructures is symmetrical with respect to a line passing through a center of the second main meta region in the first direction, a line passing through the center of the second main meta region in the second direction, a diagonal line passing through the center of the second main meta region in the first diagonal direction, and a diagonal line passing through the center of the center of the second main meta region in the second diagonal direction, and
wherein a distribution of the cross-sectional areas of the third plurality of nanostructures is symmetrical with respect to a line passing through a center of the third main meta region in the first direction, a line passing through the center of the third main meta region in the second direction, a diagonal line passing through the center of the third main meta region in the first diagonal direction, and a diagonal line passing through the center of the center of the third main meta region in the second diagonal direction.

12. The image sensor of claim 9, wherein the distribution of the cross-sectional areas of the second plurality of nanostructures is different from the distribution of the cross-sectional areas of the third plurality of nanostructures.

13. The image sensor of claim 11, wherein the distribution of the cross-sectional areas of the second plurality of nanostructures and the distribution of the cross-sectional areas of the third plurality of nanostructures are the same.

14. The image sensor of claim 9,
wherein the distribution of the cross-sectional areas of the second plurality of nanostructures is symmetrical with respect to a diagonal line passing through the center of the second main meta region and a diagonal line passing through the center of the second main meta region, and is asymmetrical with respect to a line passing through the center of the second main meta region in the first direction and a line passing through the center of the second main meta region in the second direction, and
wherein the distribution of the cross-sectional areas of the third plurality of nanostructures is symmetrical with respect to a diagonal line passing through the center of the third main meta region in the first diagonal direction and a diagonal line passing through the center of the third main meta region in the second diagonal direction, and is asymmetrical with respect to a line passing through the center of the third main meta region in the first direction and a line passing through the center of the third main meta region in the second direction.

15. The image sensor of claim 2,
wherein the plurality of light sensing devices comprises a plurality of first light sensing devices, a plurality of second light sensing devices, a plurality of third light sensing devices, a plurality of fourth light sensing devices, a plurality of fifth light sensing devices, and a plurality of sixth light sensing devices which all have a same size and are two-dimensionally arranged in a first diagonal direction and a second diagonal direction,
wherein the plurality of first light sensing devices and the plurality of second light sensing devices are alternately arranged in the second diagonal direction, and
wherein the plurality of third light sensing devices, the plurality of fourth light sensing devices, the plurality of fifth light sensing devices, and the plurality of sixth light sensing devices are repeatedly arranged in the forgoing sequence in the second diagonal direction.

16. The image sensor of claim 15,
wherein the nano-photonic lens array comprises a plurality of first meta regions corresponding to the plurality of first light sensing devices, a plurality of second meta regions corresponding to the plurality of second light sensing devices, a plurality of third meta regions corresponding to the plurality of third light sensing devices, a plurality of fourth meta regions corresponding to the plurality of fourth light sensing devices, a plurality of fifth meta regions corresponding to the plurality of fifth light sensing devices, and a plurality of sixth meta regions corresponding to the plurality of sixth light sensing devices, and
wherein each of the plurality of first meta regions, the plurality of second meta regions, the plurality of third meta regions, the plurality of fourth meta regions, the plurality of fifth meta regions, and the plurality of sixth meta regions comprises a plurality of nanostructures.

17. The image sensor of claim 16,
wherein a number of the plurality of nanostructures in the plurality of first meta regions is greater than a number of the plurality of nanostructures in the plurality of second meta regions,
wherein a number of the plurality of nanostructures in the plurality of third meta regions is greater than a number of the plurality of nanostructures in the plurality of fourth meta regions, and
wherein a number of the plurality of nanostructures in the plurality of fifth meta regions is greater than a number of the plurality of nanostructures in the plurality of sixth meta regions.

18. The image sensor of claim 16,
wherein distributions of the cross-sectional areas of the plurality of nanostructures in each of the plurality of first meta regions are symmetrical with respect to respective diagonal lines passing through centers of the plurality of first meta regions in the first diagonal direction and respective diagonal lines passing through the centers of the plurality of first meta regions in the second diagonal direction, and are asymmetrical with respect to respective lines passing through the centers of the plurality of first meta regions in the first direction and respective lines passing through the centers of the plurality of first meta regions in the second direction,
wherein distributions of the cross-sectional areas of the plurality of nanostructures in the plurality of second meta regions are symmetrical with respect to respective diagonal lines passing through centers of the plurality of second meta regions in the first diagonal direction and respective diagonal line passing through the centers of the plurality of second meta regions in the second diagonal direction, and are asymmetrical with respect to respective lines passing through the centers of the plurality of second meta regions in the first direction and respective lines passing through the centers of the plurality of second meta regions in the second direction,
wherein distributions of the cross-sectional areas of the plurality of nanostructures in the plurality of third meta regions are symmetrical with respect to respective diagonal lines passing through centers of the plurality of third meta regions in the first diagonal direction and respective diagonal lines passing through the centers of the plurality of third meta regions in the second diagonal direction, and are asymmetrical with respect to respective lines passing through the centers of the plurality of third meta regions in the first direction and respective lines passing through the centers of the plurality of third meta regions in the second direction,
wherein distributions of the cross-sectional areas of the plurality of nanostructures in the plurality of fourth meta regions are symmetrical with respect to respective diagonal lines passing through centers of the plurality of fourth meta regions in the first diagonal direction and respective diagonal lines passing through the centers of the plurality of fourth meta regions in the second diagonal direction, and are asymmetrical with respect to respective lines passing through the centers of the plurality of fourth meta regions in the first direction and respective lines passing through the centers of the plurality of fourth meta regions in the second direction,
wherein distributions of the cross-sectional areas of the plurality of nanostructures in the plurality of fifth meta regions are symmetrical with respect to respective diagonal lines passing through centers of the plurality of fifth meta regions in the first diagonal direction and respective diagonal lines passing through the centers of the plurality of fifth meta regions in the second diagonal direction, and are asymmetrical with respect to respective lines passing through the centers of the plurality of fourth meta regions in the first direction and respective lines passing through the centers of the plurality of fourth meta regions in the second direction, and distributions of the cross-sectional areas of the plurality of nanostructures in the plurality of sixth meta regions are symmetrical with respect to respective diagonal lines passing through centers of the plurality of sixth meta regions in the first diagonal direction and respective diagonal lines passing through centers of the plurality of sixth meta regions in the second diagonal direction, and are asymmetrical with respect to respective lines passing through the centers of the plurality of sixth meta regions in the first direction and respective lines passing through the centers of the plurality of sixth meta regions in the second direction.

19. An electronic apparatus comprising:
a lens assembly configured to form an optical image of a subject;
an image sensor configured to convert the optical image formed by the lens assembly into an electrical signal;
at least one memory storing one or more instructions; and
at least one processor configured to execute the one or more instructions,
wherein the one or more instructions, when executed by the at least one processor, cause the electronic apparatus to process a signal generated by the image sensor,
wherein the image sensor comprises:
a sensor substrate comprising a plurality of light sensing devices; and
a nano-photonic lens array comprising a plurality of nanostructures arranged to separate, from incident light, light in a first wavelength band, light in a second wavelength band different from the first wavelength band, and light in a third wavelength band different from the first wavelength band and the second wavelength band, and to focus the separated light onto each of the plurality of light sensing devices,
wherein the plurality of nanostructures are configured to cause light of a same wavelength to be focused onto each of two light sensing devices adjacent in a diagonal direction among the plurality of light sensing devices, and
wherein, for each of the two light sensing devices adjacent in the diagonal direction, the light of the same wavelength respectively focused thereon has a different intensity.

20. An image sensor comprising:
a sensor substrate comprising a main light sensing device and a corner light sensing device in contact with the main light sensing device; and
a nano-photonic lens array comprising a main meta region and a corner meta region,
wherein the main meta region comprises a plurality of nanostructures, and the corner meta region comprises at least one nanostructure,
wherein the plurality of nanostructures is arranged to separate light of a wavelength band from incident light,
wherein the plurality of nanostructures is configured to cause the light of the wavelength band to be focused onto the main light sensing device and the corner light sensing device, and
wherein the light of the wavelength band focused on the main light sensing device has a different intensity than the light of the wavelength band focused on the corner light sensing device.
